(19) United States
(12) Patent Application Publication
(10) Pub. No.: US 2025/0136862 A1
(43) Pub. Date: May 1, 2025

(54) LIGHT EMITTING ELEMENT, DISPLAY DEVICE INCLUDING THE LIGHT EMITTING ELEMENT, AND METHOD OF MANUFACTURING THE LIGHT EMITTING ELEMENT

(71) Applicant: Samsung Display Co., Ltd., Yongin-si (KR)

(72) Inventor: Dongjin KANG, Yongin-si (KR)

(73) Assignee: Samsung Display Co., Ltd., Yongin-si (KR)

(21) Appl. No.: 18/768,383

(22) Filed: Jul. 10, 2024

(30) Foreign Application Priority Data
Oct. 31, 2023 (KR) 10-2023-0148130

(51) Int. Cl. C09K 11/08; C09K 11/02; C09K 11/68; H10K 50/15; H10K 50/16

(52) U.S. Cl. CPC C09K 11/0811; C09K 11/02; C09K 11/682; H10K 50/15; H10K 50/16; C09K 2211/1074; C09K 2211/1077

(57) ABSTRACT

Embodiments provide a light-emitting element that includes: a first electrode, a second electrode disposed on the first electrode, an emission layer disposed between the first electrode and the second electrode and including a quantum dot, a hole transport region disposed between the first electrode and the second electrode, and an electron transport region disposed between the first electrode and the second electrode. The emission layer is disposed between the hole transport region and the electron transport region. At least one of the hole transport region and the electron transport region includes a metal nanoparticle, wherein the metal nanoparticle includes a core including a metal oxide and a ligand bonded the core. The ligand includes an acidic functional group, a basic functional group, or an ultraviolet-reactive functional group.

### CROSS-REFERENCE TO RELATED APPLICATION(S)

This application claims priority to and benefits of Korean Patent Application No. 10-2023-0148130 under 35 U.S.C. § 119, filed on Oct. 31, 2023, in the Korean Intellectual Property Office, the entire contents of which are incorporated herein by reference.

### BACKGROUND

### 1. Technical Field

The disclosure relates to a light-emitting element including a quantum dot, a display device including the light-emitting element, and a method of manufacturing the light-emitting element.

### 2. Description of the Related Art

A light-emitting element converts electrical energy into light. Among light-emitting elements, a quantum dot light-emitting element that includes a quantum dot in an emission layer has high color purity and emission efficiency and is capable of emitting multiple colors of light. In a light-emitting element, holes move to the emission layer through a hole transport region, and electrons move to the emission layer through an electron transport region. Research on efficient injection and transport of holes and electrons has been conducted to improve the efficiency of quantum dot light-emitting elements.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light-emitting element exhibiting excellent efficiency, a display device, and a method of manufacturing the light-emitting element.

According to an embodiment, a light-emitting element may include: a first electrode; a second electrode disposed on the first electrode; an emission layer disposed between the first electrode and the second electrode, the emission layer including a quantum dot; a hole transport region disposed between the first electrode and the second electrode; and an electron transport region disposed between the first electrode and the second electrode, wherein
the emission layer may be disposed between the hole transport region and the electron transport region; at least one of the hole transport region and the electron transport region may include a metal nanoparticle; the metal nanoparticle may include a core including a metal oxide, and a ligand bonded to the core, the ligand including an acidic functional group, a basic functional group, or an ultraviolet-reactive functional group; and the ultraviolet-reactive functional group may shrink or may expand when ultraviolet light is provided.

In an embodiment, the acidic functional group may include at least one of a carboxylic acid group, a phosphoric acid group, a sulfonic acid group, an amino acid group, and a boronic acid group.

In an embodiment, the ligand including the acidic functional group may be derived from at least one of acrylic acid (AAc), methacrylic acid (MAAc), ethylacrylic acid (EAAc), propylacrylic acid (PAAc), 4-vinylbenzoic acid (VBA), itaconic acid (IA), ethylene glycol acrylate phosphate (EGAP), vinylphosphonic acid (VPA), ethylene glycol methacrylate phosphate (EGMP), 4-vinyl-benzyl phosphonic acid (VBPA), vinylsulfonic acid (VSA), 4-styrenesulfonic acid (SSA), 2-acrylamido-2-methylpropane sulfonic acid (AMPS), 3-sulfopropyl methacrylate potassium salt (KSPMA), aspartic acid (ASA), L-glutamic acid (LGA), histidine (HIS), vinylphenyl boronic acid (VPBA), and 3-acrylamidophenyl boronic acid (AAPBA).

In an embodiment, the basic functional group may include at least one of an amine group, a morpholino group, a pyrrolidine group, a piperazine group, a pyridine group, and an imidazole group.

In an embodiment, the ligand including the basic functional group may be derived from at least one of (2-dimethylamino)ethyl methacrylate (DMA), (2-diethylamino)ethyl methacrylate (DEA), (2-dipropylamino)ethyl methacrylate (DPAEMA), (2-diisopropylamino)ethyl methacrylate (DPA), N-(3-(dimethylamino)-propyl)methacrylamide (DMAPMAm), (2-dimethylamino)ethyl acrylate (DMAEA), 2-(tert-butylamino)ethyl methacrylate (tBAEMA), N,N-dimethylvinylbenzylamine, N,N-diethylvinylbenzylamine, N,N-dipropylvinylbenzylamine, (2-diethylamino)ethyl acrylamide (DEAm), (2-N-morpholino)ethyl methacrylate (MEMA), acryloylmorpholine (AM), (2-N-morpholino)ethyl methacrylamide (MEMAm), N-ethylpyrrolidine methacrylate (EPyM), N-acryloyl-N′-methyl piperazine, N-acryloyl-N′-ethyl piperazine, N-acryloyl-N′-propyl piperazine, 4-vinylpyridine (4VP), 2-vinylpyridine (2VP), N-vinylimidazole (VI), 6-(1H-imidazol-1-yl)hexyl-methacrylate (imHeMA), poly(propylenimine) dendrimer (PPI), poly(ethylenimine) dendrimer (PEI), and poly(amidoamine) dendrimer (PAMAM).

In an embodiment, the ultraviolet-reactive functional group may include at least one of a spiropyran group and a merocyanine group.

In an embodiment, the ligand including the ultraviolet-reactive functional group may be derived from at least one compound selected from Compound Group 1.

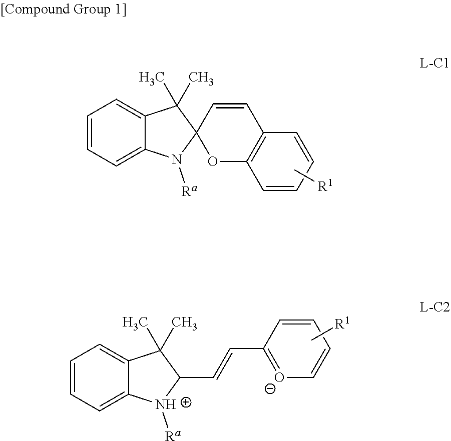

In Compound Group 1, R^{a} may be a substituted or unsubstituted alkyl group having 1 to 20 carbon atoms; and R¹ may be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or the metal oxide may be represented by Formula M-1.

Zn_{q}Me_{(1-q)}O [Formula M-1]

In Formula M-1, q may be a real number from 0 to 0.5; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

In an embodiment, the quantum dot may include a core part including an inorganic compound, and a ligand part that is bonded to the core part; and the ligand part may include the acidic functional group or the basic functional group.

In an embodiment, the electron transport region may include the metal nanoparticle; and the ligand may include the acidic functional group or the ultraviolet-reactive functional group.

In an embodiment, the hole transport region may include the metal nanoparticle; and the ligand may include the basic functional group or the ultraviolet-reactive functional group.

In an embodiment, the hole transport region may be disposed between the first electrode and the emission layer; and the electron transport region may be disposed between the emission layer and the second electrode.

In an embodiment, the hole transport region may be disposed between the emission layer and the second electrode; and the electron transport region may be disposed between the first electrode and the emission layer.

According to an embodiment, a display device may include a display element layer disposed on a base layer, wherein
the display element layer may include a first light emitting element, a second light emitting element, and a third light emitting element, each emitting light in a different wavelength region; the first, second, and third light-emitting elements may each include a first electrode, a second electrode disposed on the first electrode, an emission layer disposed between the first electrode and the second electrode, a hole transport region disposed between the first electrode and the second electrode, and an electron transport region disposed between the first electrode and the second electrode; the emission layer may be disposed between the hole transport region and the electron transport region; at least one of the first to third light-emitting elements may each include a quantum dot in the emission layer; the remainder of the first to third light-emitting elements may each include an organic emission material in the emission layer; the light-emitting element including the quantum dot may include a metal nanoparticle in at least one of the hole transport region and the electron transport region; the metal nanoparticle may include a core including a metal oxide, and a ligand bonded to the core, the ligand including an acidic functional group, a basic functional group, or an ultraviolet-reactive functional group; and the ultraviolet-reactive functional group may shrink or may expand when ultraviolet light is provided.

In an embodiment, the first light-emitting element may emit blue light; the second light-emitting element may emit green light; and the third light-emitting element may emit red light.

In an embodiment, the first light-emitting element may include a first quantum dot emitting first light; the second light-emitting element may include a second quantum dot emitting second light, which has a wavelength region that is different from the first light; and the third light-emitting element may include an organic emission material emitting third light, which has a wavelength region that is different from the first light and the second light.

In an embodiment, the first light-emitting element may include a quantum dot emitting first light; the second light-emitting element may include a first organic emission material emitting second light, which has a wavelength region that is different from the first light; and the third light-emitting element may include a second organic emission material emitting third light, which has a wavelength region that is different from the first light and the second light.

In an embodiment, the first light-emitting element may include a first quantum dot emitting first light; the second light-emitting element may include a second quantum dot emitting second light, which has a wavelength region that is different from the first light; and the third light-emitting element may include a third quantum dot emitting third light, which has a wavelength region that is different from the first light and the second light.

In an embodiment, the acidic functional group may include at least one of a carboxylic acid group, a phosphoric acid group, a sulfonic acid group, an amino acid group, and a boronic acid group.

In an embodiment, the basic functional group may include at least one of an amine group, a morpholino group, a pyrrolidine group, a piperazine group, a pyridine group, and an imidazole group.

In an embodiment, the ligand including the ultraviolet-reactive functional group may be derived from at least one compound selected from Compound Group 1.

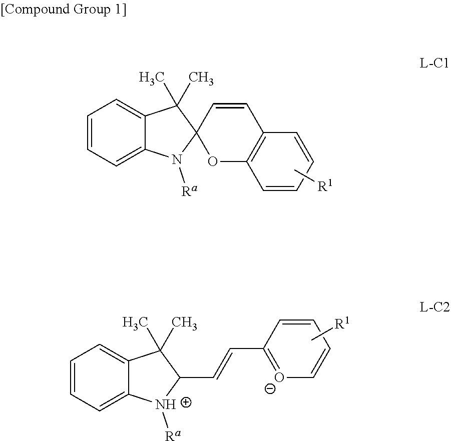

In Compound Group 1, R^{a} may be a substituted or unsubstituted alkyl group having 1 to 20 carbon atoms; and R¹ may be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or the metal oxide may be represented by Formula M-1.

Zn_{q}Me_{(1-q)}O [Formula M-1]

In Formula M-1, q may be a real number from 0 to 0.5; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

According to an embodiment, a method of manufacturing a light-emitting element may include: preparing a preliminary light-emitting element; and forming a light-emitting element by providing, to the preliminary light-emitting element, an acidic material, a basic material, or ultraviolet light, wherein
the preparing of the preliminary light-emitting element may include: forming a first electrode; forming an emission layer by providing a quantum dot on the first layer; forming a second electrode on the emission layer; forming a hole transport region; and forming an electron transport region;
one step among the forming of the hole transport region and the forming of the electron transport region may be performed between the forming of the first electrode and the forming of the emission layer; the remaining step among the forming of the hole transport region and the forming of the electron transport region may be performed between the forming of the emission layer and the forming of the second electrode; at least one of the forming of the hole transport region and the forming of the electron transport region may include providing a composition that contains a preliminary metal nanoparticle;
the preliminary metal nanoparticle may include: a core including a metal oxide; and a preliminary ligand bonded to the core, the ligand including an acidic functional group, a basic functional group, or an ultraviolet-reactive functional group and bonded to the core; and
the ultraviolet-reactive functional group may shrink or may expand when the ultraviolet light is provided.

In an embodiment, the preliminary ligand may shrink or may expand to form a ligand when the acidic material, the basic material, or the ultraviolet light is provided.

In an embodiment, the acidic material may include at least one of isobutyric acid and citric acid.

In an embodiment, the basic material may include ammonia.

In an embodiment, the composition may be provided through an inkjet printing method or through a dispensing method.

In an embodiment, the acidic functional group may include at least one of a carboxylic acid group, a phosphoric acid group, a sulfonic acid group, an amino acid group, and a boronic acid group.

In an embodiment, the basic functional group may include at least one of an amine group, a morpholino group, a pyrrolidine group, a piperazine group, a pyridine group, and an imidazole group.

In an embodiment, the ligand including the ultraviolet-reactive functional group may be derived from at least one compound selected from Compound Group 1.

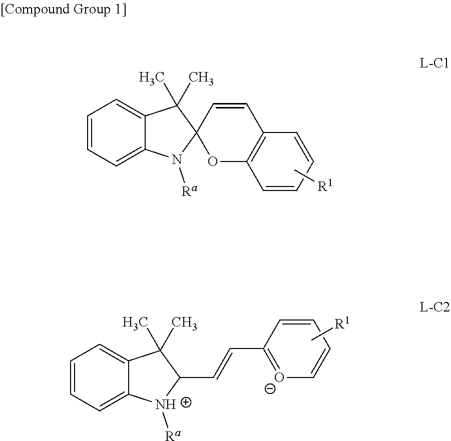

In Compound Group 1, R^{a} may be a substituted or unsubstituted alkyl group having 1 to 20 carbon atoms; and R¹ may be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or the metal oxide may be represented by Formula M-1.

Zn_{q}Me_{(1-q)}O [Formula M-1]

In Formula M-1, q may be a real number from 0 to 0.5; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is a schematic cross-sectional view of a part taken along virtual line I-I′ in FIG. 1;

FIG. 3 is a schematic plan view of a display device according to an embodiment;

FIG. 4A is a schematic cross-sectional view of a part of a display device taken along virtual line II-II′ in FIG. 3;

FIG. 4B is a schematic cross-sectional view of a part of a display device taken along virtual line II-II′ in FIG. 3 according to another embodiment;

FIG. 4C is a schematic cross-sectional view of a part of a display device taken along virtual line II-II′ in FIG. 3 according to another embodiment;

FIG. 4D is a schematic cross-sectional view of a part of a display device taken along virtual line II-II′ in FIG. 3 according to another embodiment;

FIG. 5A to FIG. 5D are each a schematic cross-sectional view of a light emitting element according to an embodiment;

FIG. 6A to FIG. 6D are each a schematic cross-sectional view of a light emitting element according to an embodiment;

FIG. 7 is a schematic cross-sectional view of a quantum dot according to an embodiment;

FIG. 8 is a schematic cross-sectional view of a metal nanoparticle according to an embodiment;

FIG. 9 is a flow chart showing a method of manufacturing a light-emitting element according to an embodiment;

FIG. 10 is a schematic cross-sectional view showing steps of manufacturing a light-emitting element according to an embodiment;

FIG. 11 is an enlarged schematic view showing steps of manufacturing a light-emitting element according to an embodiment;

FIG. 12A is a schematic cross-sectional view showing steps of manufacturing a light-emitting element according to an embodiment;

FIG. 12B is a schematic cross-sectional view showing steps of manufacturing a light-emitting element according to an embodiment;

FIG. 13 is an enlarged schematic view showing steps of manufacturing a light-emitting element according to an embodiment;

FIG. 14 is a graph showing evaluated data of light-emitting elements according to the Examples; and

FIG. 15 is a graph showing the evaluated data of light-emitting elements according to the Examples.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

In the specification, the expressions used in the singular such as “a,” “an,” and “the,” are intended to include the plural forms as well, unless the context clearly indicates otherwise.

In the specification, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amine group, an amino group, a silyl group, an oxy group, a thio group, a sulfinyl group, a sulfonyl group, a carbonyl group, a boron group, a phosphine group, an oxide group, a phosphine sulfide group, an alkyl group, an alkenyl group, a alkynyl group, a hydrocarbon cyclic group, an aryl group, and a hetero cyclic group. Each of the substituents listed above may itself be substituted or unsubstituted. For example, a biphenyl group may be interpreted as an aryl group, or it may be interpreted as a phenyl group substituted with a phenyl group.

In the specification, examples of a halogen atom may include a fluorine atom, a chlorine atom, a bromine atom, and an iodine atom.

In the specification, an alkyl group may be linear, branched, or cyclic. The number of carbon atoms in an alkyl group may be 1 to 50, 1 to 30, 1 to 20, 1 to 10 or 1 to 6. Examples of an alkyl group may include a methyl group, an ethyl group, an n-propyl group, an isopropyl group, a cyclopropyl group, an n-butyl group, an s-butyl group, a t-butyl group, an i-butyl group, a 2-ethylbutyl group, a 3,3-dimethyl butyl group, a cyclobutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, a cyclopentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, a cycloheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, a cyclononyl group, an n-decyl group, a cyclodecyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, a norbornyl group, a 1-adamantyl group, a 2-adamantyl group, an isobornyl group, and a bicycloheptyl group, but embodiments are not limited thereto.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexphenyl group, a triphenylenyl group, a pyrenyl group, a benzofluoranthenyl group, a chrysenyl group, etc., but embodiments are not limited thereto.

In the specification, a heteroaryl group may include at least one of B, O, N, P, Si, and S as a heteroatom. When a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, a N-arylcarbazole group, a N-heteroarylcarbazole group, a N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, and a dibenzofuran group, etc., but embodiments are not limited thereto.

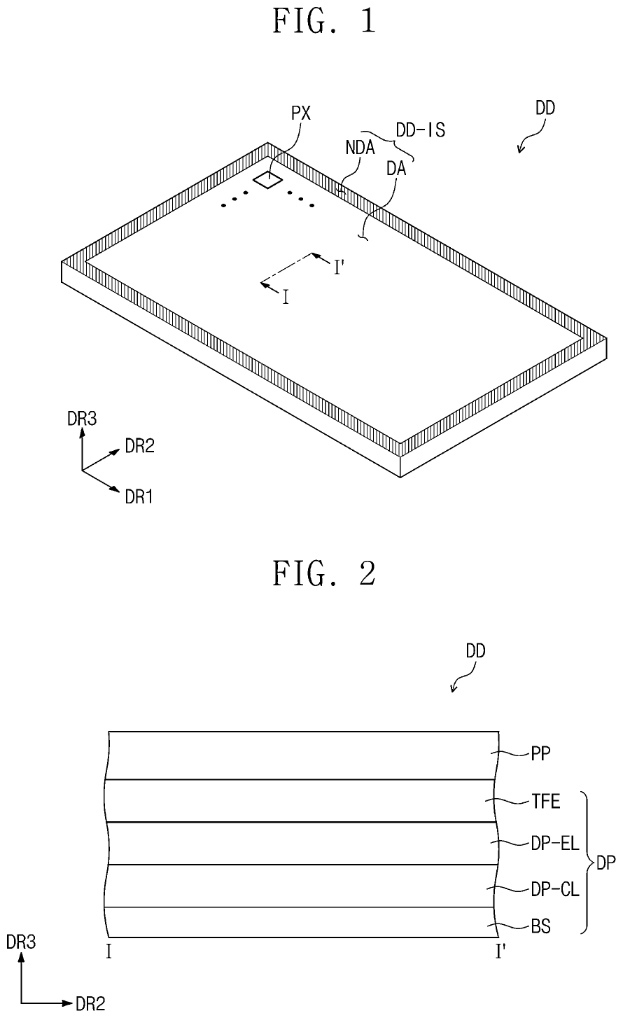

Hereinafter, a light-emitting element according to an embodiment and a display device including the light-emitting element will be described in detail with reference to the accompanying drawings. FIG. 1 is a schematic perspective view of a display device DD according to an embodiment.

Referring to FIG. 1, the display device DD according to an embodiment may be activated in response to electrical signals. For example, the display device DD may be a large-sized device such as a television, a monitor, or a billboard. In an embodiment, the display device DD may be a small or medium-sized device, such as a personal computer, a laptop, a personal digital terminal, a navigation device, a game console, a smartphone, a tablet, or a camera. However, these are merely provided as examples, and the display device DD may also be included in other devices.

The display device DD may display an image (or a video) through a display surface DD-IS. The display surface DD-IS may be parallel to a plane that is defined by a first direction axis DR1 and a second direction axis DR2. The display surface DD-IS may include a display region DA and a non-display region NDA.

A pixel PX may be disposed in the display region DA, and the pixel PX may not be disposed in the non-display region NDA. The non-display region NDA may be defined along an edge of the display surface DD-IS. The non-display region NDA may surround the display region DA. However, embodiments are not limited thereto. For example, the non-display region NDA may be omitted, or the non-display region NDA may be disposed only on one side of the display region DA.

FIG. 1 illustrates that the display device DD has a display surface DD-IS that is flat. However, embodiments are not limited thereto. For example, in embodiments, the display surface DD-IS of the display device DD may be a curved display surface or a three-dimensional display surface. For example, a three-dimensional display surface may include multiple display regions disposed in different directions.

In FIG. 1 and the following drawings, first direction axis DR1, a second direction axis DR2, and/or a third direction axis DR3 are illustrated. In the specification, the directions that are indicated by the first to third direction axes DR1, DR2, and DR3 are relative terms, and may thus be changed into other directions. The directions indicated by the first to third direction axes DR1, DR2, and DR3 may be respectively described as first to third directions, and the same reference numerals and symbols may be used. In the specification, the first direction axis DR1 and the second direction axis DR2 may be perpendicular to each other, and the third direction DR3 may be a normal direction with respect to a plane that is defined by the first direction axis DR1 and the second direction axis DR2.

In the specification, a plan view may refer to the plane defined by the first direction axis DR1 and the second direction axis DR2, and a cross-sectional view may refer to a surface that is perpendicular to the plane that is defined by the first direction axis DR1 and the second direction axis DR2 and is parallel to the third direction axis DR3. A thickness direction of the display device DD may be parallel to the third direction DR3, which is a normal direction with respect to the plane defined by the first direction DR1 and the second direction DR2.

In the specification, an upper surface (or a front surface) and a lower surface (or a rear surface) of each of the members constituting the display device DD may be defined with respect to the third direction DR3. For example, a surface that is relatively adjacent to the display surface DD-IS among two surfaces facing each other with respect to the third direction DR3 may be defined as a front surface (or an upper surface), and a surface that is relatively spaced apart in the third direction DR3 from the display surface DD-IS, with the front surface (or the upper surface) between that surface and the display surface DD-IS, may be defined as a rear surface (or a lower surface). In the specification, an upper part (or upper side) or a lower part (or a lower side) may be defined with respect to the third direction DR3, the upper part (or the upper side) may be defined in a direction toward the display surface DD-IS, and the lower part (or the lower side) may be defined in a direction away from the display surface DD-IS.

FIG. 2 is a schematic cross-sectional view of a part taken along virtual line I-I′ in FIG. 1. FIG. 2 is a schematic cross-sectional view of the display device DD according to an embodiment.

The display device DD may include a display panel DP and an optical layer PP disposed on the display panel DP. The display panel DP may include a base layer BS, a circuit layer DP-CL disposed on the base layer BS, a display element layer DP-EL disposed on the circuit layer DP-CL, and an encapsulation layer TFE disposed on the display element layer DP-EL.

In embodiments, an image may be substantially generated by the display panel DP. The display panel DP may be a light emitting display panel. For example, the display panel DP may be an organic light emitting display panel, an inorganic light emitting display panel, an organic-inorganic light emitting display panel, or a quantum dot light emitting display panel.

The base layer BS may provide a base surface on which the circuit layer DP-CL is disposed. The base layer BS may be a rigid substrate; or the base layer BS may be a flexible substrate that is capable of being bent, folded, rolled, or the like. The base layer BS may be a glass substrate, a metal substrate, a polymer substrate, etc. However, embodiments are not limited thereto, and the base layer BS may include an inorganic layer, an organic layer, or a composite material layer.

The circuit layer DP-CL may be disposed on the base layer BS. The circuit layer DP-CL may include an insulating layer, a semiconductor pattern, a conductive pattern, signal lines, etc. After an insulating layer, a semiconductor layer, and a conductive layer are formed on the base layer BS by processes such as coating or deposition, the insulating layer, the semiconductor layer, and the conductive layer may be selectively patterned by photolithography processes. Thereafter, a semiconductor pattern, a conductive pattern, and signal lines included in the circuit layer DP-CL may be formed.

The display element layer DP-EL may be disposed on the circuit layer DP-CL. The display element layer DP-EL may include a pixel definition film PDL (see FIG. 4A to FIG. 4D), and first to third light-emitting elements ED-1, ED-2, and ED-3 (see FIG. 4A to FIG. 4D), which will be described later. For example, the display element layer DP-EL may include organic emission materials, inorganic emission materials, organic-inorganic emission materials, quantum dots, quantum rods, micro-LEDs, or nano LEDs. In an embodiment, the display element layer DP-EL may include quantum dots.

The encapsulation layer TFE may protect the display element layer DP-EL from moisture, oxygen, and foreign materials such as dust particles. The encapsulation layer TFE may include at least one inorganic layer. In an embodiment, the encapsulation layer TFE may have a structure in which an inorganic layer, an organic layer, and an inorganic layer are sequentially stacked.

The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted.

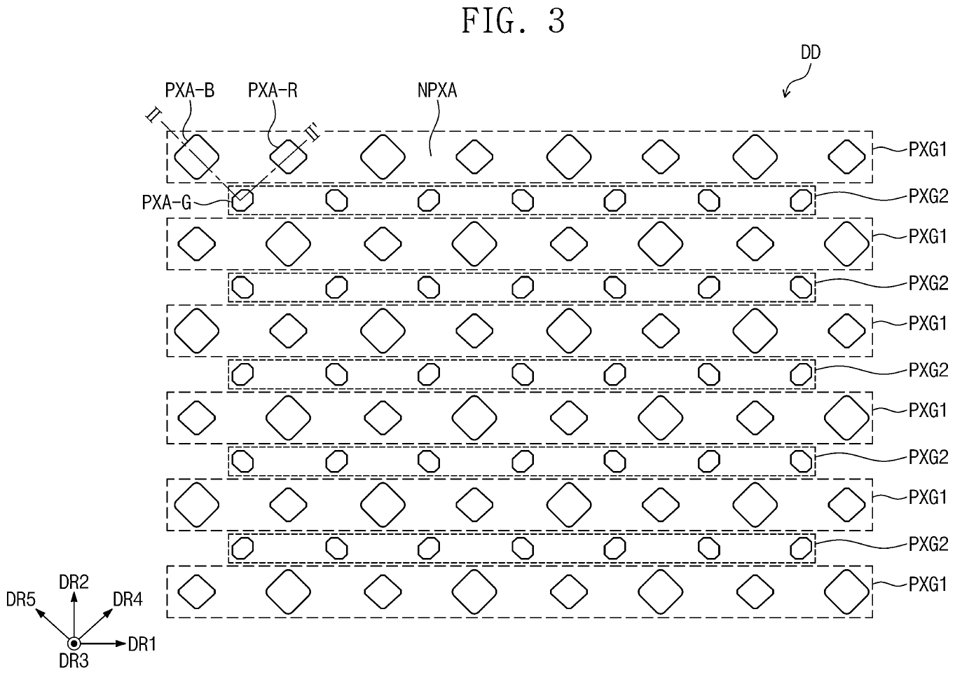

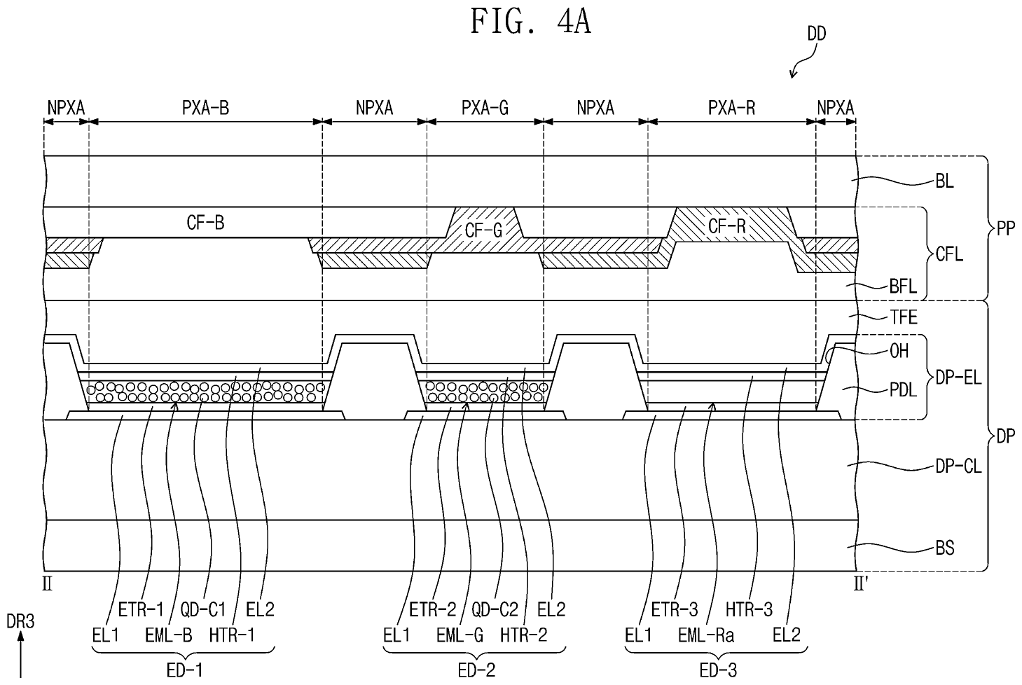

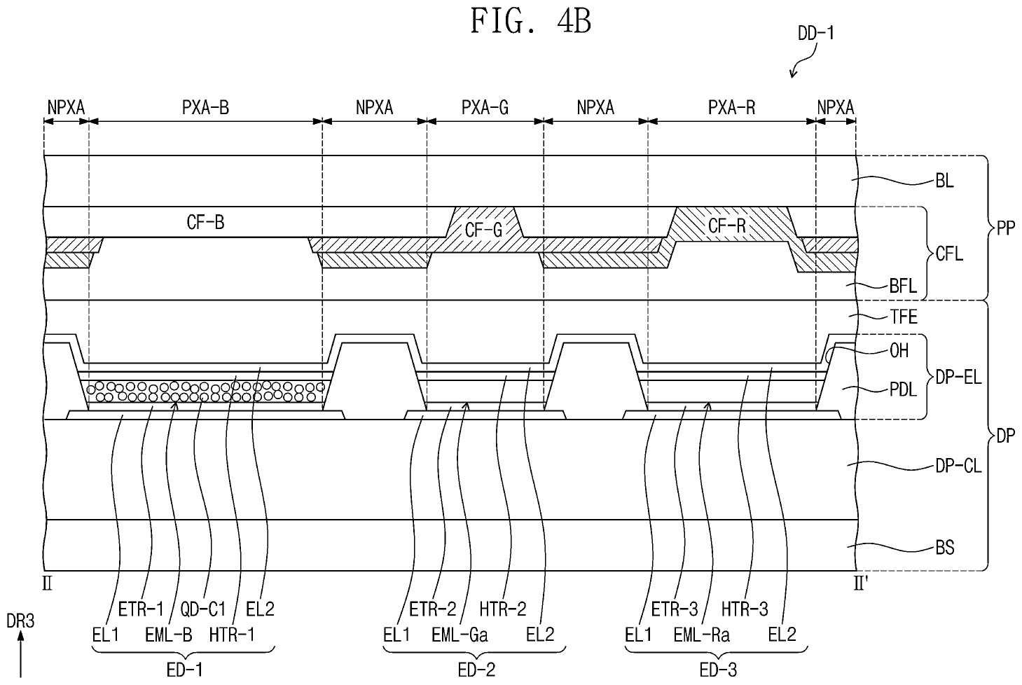

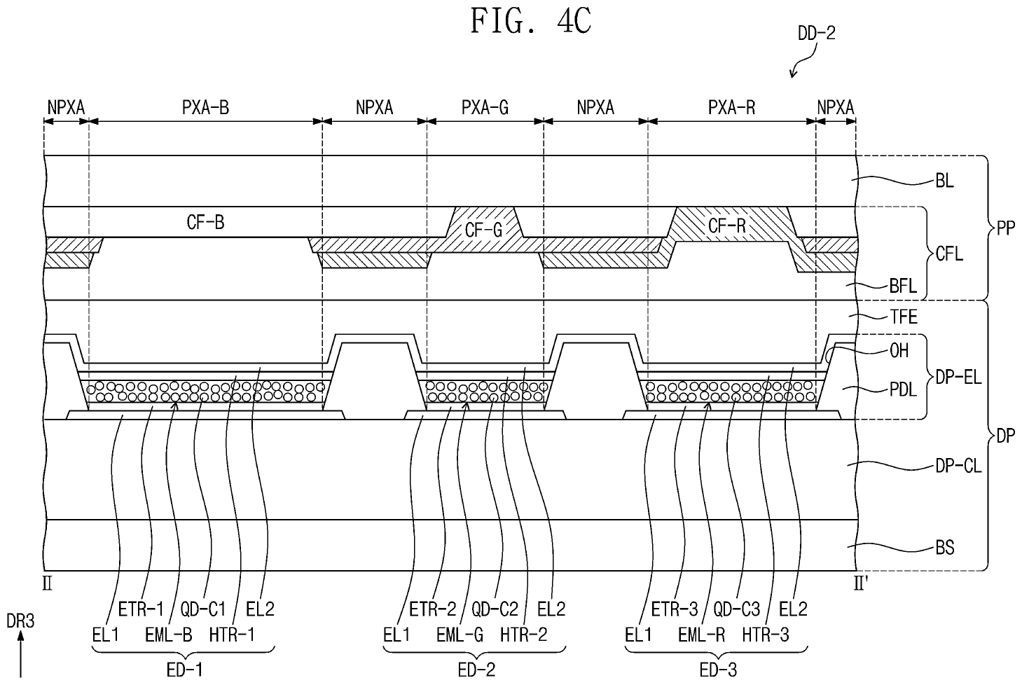

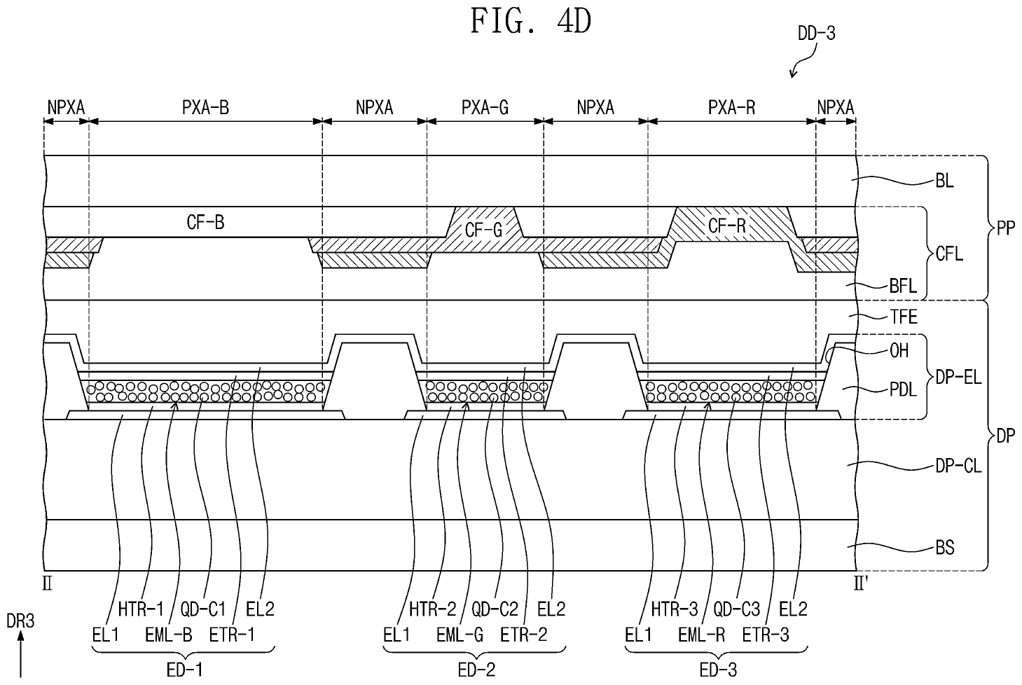

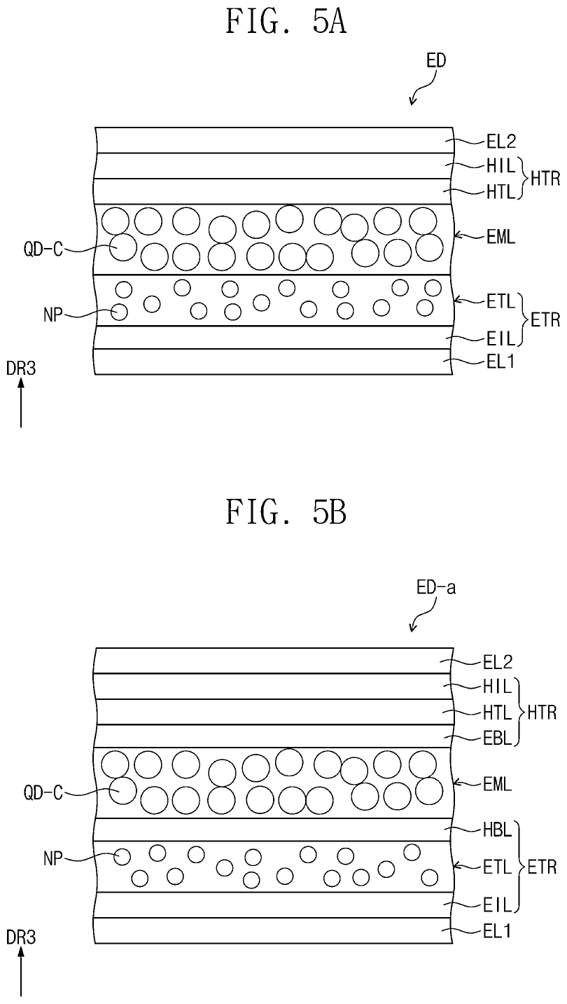

FIG. 3 is a schematic plan view of the display device DD according to an embodiment. FIG. 4A is a schematic cross-sectional view of a portion taken along virtual line II-II′ in FIG. 3. FIG. 3 may be a schematic plan view illustrating a display region DA (see FIG. 1) of the display device DD. FIG. 4A may be a schematic cross-sectional view illustrating a part of the display device DD according to an embodiment.

Referring to FIG. 3 and FIG. 4A, the display device DD may include a peripheral region NPXA and emission regions PXA-B, PXA-G, and PXA-R. The emission regions PXA-B, PXA-G, and PXA-R may emit light respectively generated from the light-emitting elements ED-1, ED-2, and ED-3. The emission regions PXA-B, PXA-G, and PXA-R may each have a different area, in which the area may refer to an area in a plan view.

The emission regions PXA-B, PXA-G, and PXA-R may be arranged into groups according to the colors of light generated from the light-emitting elements ED-1, ED-2, and ED-3. Three emission regions PXA-B, PXA-G, and PXA-R respectively emitting blue light, green light, and red light are shown as examples in FIG. 3 and FIG. 4A. For example, the display device DD may include a blue emission region PXA-B, a green emission region PXA-G, and a red emission region PXA-R, which are distinct from each other.

The display panel DP may include multiples of the light-emitting elements ED-1, ED-2, and ED-3, each emitting light in a different wavelength region. The light-emitting elements ED-1, ED-2, and ED-3 may emit light with colors that are different from each other. For example, the display panel DP may include a first light-emitting element ED-1 emitting blue light, a second light-emitting element ED-2 emitting green light, and a third light-emitting element ED-3 emitting red light. However, embodiments are not limited thereto, and the first to third light-emitting elements ED-1, ED-2, and ED-3 may emit light in a same wavelength region, or at least one light-emitting element may emit light in a wavelength region that is different from the remainder.

In the display device DD according to an embodiment as illustrated in FIG. 3 and FIG. 4A, emission regions PXA-B, PXA-G, and PXA-R may have areas that are different in size or shape from each other, depending on the colors of light that are emitted from the emission layers EML-B, EML-G, and EML-R of the respective light-emitting elements ED-1, ED-2, and ED-3. The blue emission region PXA-B of the first light-emitting element ED-1, which emits blue light, may have a largest area, and the green emission region PXA-G of the second light-emitting element ED-2, which emits green light, may have a smallest area. However, embodiments are not limited thereto, and the emission regions PXA-B, PXA-G, and PXA-R may emit light of other colors than red light, green light, and blue light. In an embodiment, the emission regions PXA-B, PXA-G, and PXA-R may each have a same area or they may have areas that are provided at different proportions from what is illustrated in FIG. 3.

The emission regions PXA-B, PXA-G, and PXA-R may be separated from each other by the pixel definition film PDL. The peripheral regions NPXA may be regions between the adjacent emission regions PXA-B, PXA-G, and PXA-R and which may correspond to the pixel definition film PDL. In an embodiment, the emission regions PXA-B, PXA-G, and PXA-R may each correspond to a pixel.

The pixel definition film PDL may define the emission regions PXA-B, PXA-G, and PXA-R. The emission regions PXA-B, PXA-G, and PXA-R and the peripheral region NPXA may be separated by the pixel definition film PDL.

The blue emission regions PXA-B and the red emission regions PXA-R may be alternately arranged along the first direction DR1 to form a first group PXG1. The green emission regions PXA-G may be arranged along the first direction axis DR1 to form a second group PXG2. The first group PXG1 may be disposed apart from the second group PXG2 along the second direction DR2. The first group PXG1 and the second group PXG2 may be provided in a repeating pattern. The first groups PXG1 and the second groups PXG2 may be alternately arranged along the second direction DR2.

A red emission region PXA-R may be disposed apart from a green emission region PXA-G in a fourth direction DR4. A blue emission region PXA-B may be disposed apart from a green emission region PXA-G in a fifth direction DR5. The fourth direction DR4 may be a direction between the first direction DR1 and the second direction DR2. The fifth direction DR5 may cross the fourth direction DR4 and may be inclined with respect to the second direction DR2.

An arrangement of the emission regions PXA-B, PXA-G, and PXA-R is not limited to what is illustrated in FIG. 3. For example, in an embodiment, the red emission region PXA-R, the green emission region PXA-G, and the blue emission region PXA-B may be arranged in this order as a repeating sequence along the first direction axis DR1. In an embodiment, a shape of each of the emission regions PXA-B, PXA-G, and PXA-R in a plan view is not limited to what is illustrated in FIG. 3 and may each have a shape that is different from what is illustrated.

In the display device DD (for example, as shown in FIG. 4A), the base layer BS may have a single-layered structure or a multilayered structure. In an embodiment, the base layer BS may include a first synthetic resin layer, an interlayer having a single-layered or multilayered structure, and a second synthetic resin layer, which may be stacked in that order. The interlayer may be referred to as a base barrier layer. The interlayer may include a silicon oxide (SiOₓ) layer and an amorphous silicon (a-Si) layer disposed on the silicon oxide layer, but embodiments are not limited thereto. For example, the interlayer may include at least one of a silicon oxide layer, a silicon nitride layer, a silicon oxynitride layer, and an amorphous silicon layer.

The first and second synthetic resin layers may each include a polyimide-based resin.

In an embodiment, the first and second synthetic resin layers may each independently include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the specification, the term “X-based resin” refers to a resin containing an “X” functional group.

The circuit layer DP-CL may be disposed on the base layer BS, and the circuit layer DP-CL may include a transistors (not shown). The transistors (not shown) may each include a control electrode, an input electrode, and an output electrode. For example, the circuit layer DP-CL may include a switching transistor and a driving transistor for driving the first to third light-emitting elements ED-1, ED-2, and ED-3 of the display element layer DP-EL.

The display element layer DP-EL may include a pixel definition film PDL and first to third light-emitting elements ED-1, ED-2, and ED-3. The pixel definition film PDL may be a layer in which an opening OH is defined. The pixel definition film PDL may separate the first to third light-emitting elements ED-1, ED-2, and ED-3. The emission layers EML-B, EML-G, and EML-Ra of the first to third light-emitting elements ED-1, ED-2, and ED-3 may each be disposed in the openings OH defined in the pixel definition film PDL and separated from each other.

The pixel definition film PDL may be formed of a polymer resin. For example, the pixel definition film PDL may include a polyacrylate-based resin or a polyimide-based resin. In embodiments, the pixel definition film PDL may include a light-absorbing material or may include a black pigment or a black dye. The pixel definition film PDL including a black pigment or a black dye may be implemented as a black pixel definition film. When forming the pixel definition film PDL, carbon black and the like may be used as a black pigment or a black dye, but embodiments are not limited thereto.

In an embodiment, the pixel definition film PDL may be formed of inorganic materials. For example, the pixel definition film PDL may include inorganic materials such as silicon nitride (SiNₓ), silicon oxide (SiOₓ), and silicon oxynitride (SiOₓN_{y}).

The first to third light-emitting elements ED-1, ED-2, and ED-3 may each include a first electrode EL1, a second electrode EL2 disposed on the first electrode EL1, emission layers EML-B, EML-G, EML-Ra disposed between the first electrode EL1 and the second electrode EL2, electron transport regions ETR-1, ETR-2, and ETR-3 disposed between the first electrode EL1 and the second electrode EL2, and hole transport regions HTR-1, HTR-2, and HTR-3 disposed between the first electrode EL1 and the second electrode EL2. The emission layers EML-B, EML-G, and EML-Ra may be respectively disposed between the electron transport regions ETR-1, ETR-2, and ETR-3 and the hole transport regions HTR-1, HTR-2, and HTR-3.

Referring to FIG. 4A, the first to third light-emitting elements ED-1, ED-2, and ED-3 may each include a first electrode EL1, a second electrode EL2 disposed on the first electrode EL1, emission layers EML-B, EML-G, and EML-Ra disposed between the first electrode EL1 and the second electrode EL2, electron transport regions ETR-1, ETR-2, and ETR-3 disposed between the first electrode EL1 and the emission layers EML-B, EML-G, and EML-Ra, and hole transport regions HTR-1, HTR-2, and HTR-3 disposed between the emission layers EML-B, EML-G, and EML-Ra and the second electrode EL2.

At least a portion of the first electrode EL1 may be exposed in an opening OH of the pixel definition film PDL. The first electrode EL1 may have conductivity. The first electrode EL1 may be formed of a metal material, a metal alloy, or a conductive compound. The first electrode EL1 may be a cathode or anode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure including a reflective or transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layered structure of ITO/Ag/ITO, but embodiments are not limited thereto. In embodiments, the first electrode EL1 may include the above-described metal materials, a combination of two or more metal materials selected from among the above-described metal materials, or an oxide of the above-described metal materials, etc. The first electrode EL1 may have a thickness in a range of about 700 Å to about 10,000 Å. For example, the first electrode EL1 may have the thickness in a range of about 1,000 Å to about 3,000 Å.

The second electrode EL2 may be a common electrode. The second electrode EL2 may be an anode or a cathode, but embodiments are not limited thereto. For example, when the first electrode EL1 is an anode, the second electrode EL2 may be a cathode, and when the first electrode EL1 is a cathode, the second electrode EL2 may be an anode. The second electrode EL2 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may be formed of a transparent metal oxide such as indium tin oxide (ITO), indium zinc oxide (IZO), zinc oxide (ZnO), and indium tin zinc oxide (ITZO).

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayered structure including a reflective or transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or an oxide of the above-described metal materials.

Although not shown in the drawings, the second electrode EL2 may be electrically connected to an auxiliary electrode. If the second electrode EL2 is electrically connected to an auxiliary electrode, resistance of the second electrode EL2 may decrease.

The emission layers EML-B, EML-G, and EML-Ra may each be disposed between the first electrode EL1 and the second electrode EL2. The first light-emitting element ED-1 may include a first emission layer EML-B, the second light-emitting element ED-2 may include a second emission layer EML-G, and the third light-emitting element ED-3 may include a third emission layer EML-Ra. At least one of the first to third light-emitting elements ED-1, ED-2, and ED-3 may each include a quantum dot, and the remainder of the first to third light-emitting elements ED-1, ED-2, and ED-3 may each include an organic emission material. For example, at least one of the first to third light-emitting elements ED-1, ED-2, and ED-3 may each be a quantum dot light-emitting element, and the remainder of the first to third light-emitting elements ED-1, ED-2, and ED-3 may each be an organic light-emitting element.

In another embodiment, the first to third light-emitting elements ED-1, ED-2, and ED-3 may each include a quantum dot.

Referring to FIG. 4A, the first emission layer EML-B may include a first quantum dot QD-C1, the second emission layer EML-G may include a second quantum dot QD-C2, and the third emission layer EML-Ra may include an organic emission material. The first quantum dot QD-C1 of the first light-emitting element ED-1 may emit blue light. The second quantum dot QD-C2 of the second light-emitting element ED-2 may emit green light. The third emission layer EML-Ra may include an organic emission material that emits red light.

For example, the third emission layer EML-Ra may include a host material and a dopant material. The third emission layer EML-Ra may include an anthracene derivative, a pyrene derivative, a fluoranthene derivative, a chrysene derivative, a dihydrobenzanthracene derivative, or a triphenylene derivative. In an embodiment, the third emission layer EML-Ra may include a styryl derivative (e.g., 1, 4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene or a derivative thereof (e.g., 2, 5, 8, 11-tetra-t-butylperylene (TBP)), pyrene or a derivative thereof (e.g., 1, 1-dipyrene, 1, 4-dipyrenylbenzene, 1, 4-bis(N, N-diphenylamino)pyrene), etc. However, embodiments are not limited thereto, and an organic emission material included in the third emission layer EML-Ra is not limited thereto.

The quantum dots QD-C1 and QD-C2 respectively included in the emission layers EML-B and EML-G may each be stacked to thereby form at least one layer. FIG. 4A shows, as an example, that the quantum dots QD-C1 and QD-C2, which each has a circular shaped cross-section, are arranged to thereby form approximately two layers, but embodiments are not limited thereto. For example, an arrangement of the quantum dots QD-C1 and QD-C2 may differ depending on a thickness of the emission layers EML-B and EML-G, or an arrangement may differ depending on a shape and an average diameter of the quantum dots QD-C1 and QD-C2 included in the emission layers EML-B and EML-G. For example, in the emission layers EML-B and EML-G, the quantum dots QD-C1 and QD-C2 may be arranged to have a single-layered configuration, or may be arranged to have a multilayered configuration, such as two layers or three layers.

In FIG. 4A, the first and second quantum dots QD-C1 and QD-C2 are each illustrated as having a substantially similar diameter, but embodiments are not limited thereto. The first and second quantum dots QD-C1 and QD-C2 may each have a different diameter. For example, the first quantum dot QD-C1 in the first light-emitting element ED-1, which emits light in a relatively short wavelength region, may have a relatively smaller average diameter than the second quantum dot QD-C2 in the second light-emitting element ED-2, which emits light in a longer wavelength region. In the specification, an average diameter may be an arithmetic average of particle diameters of the quantum dots. In the specification, a particle diameter of a quantum dot may be an average value of the widths of a quantum dot particle as measured on a cross-section thereof.

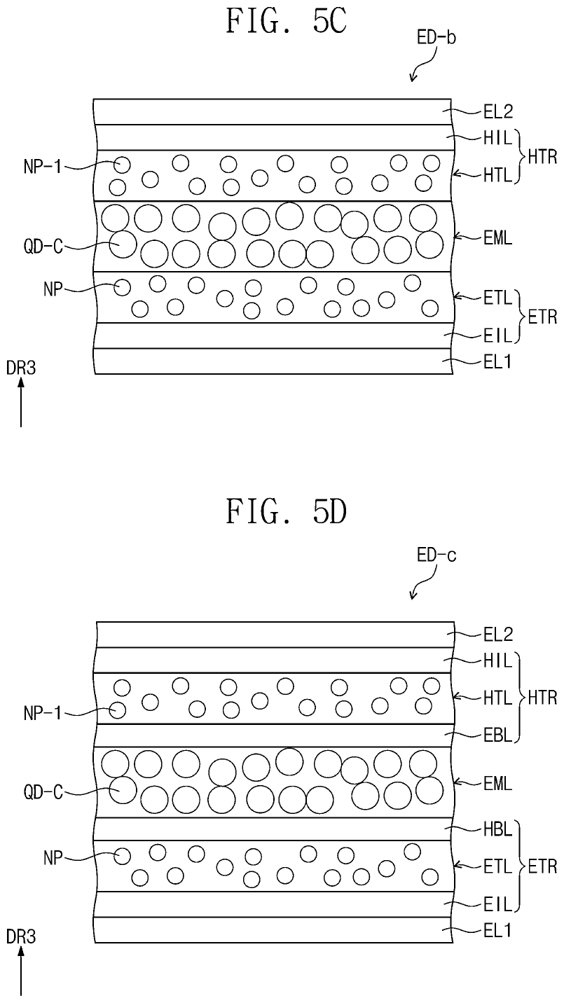

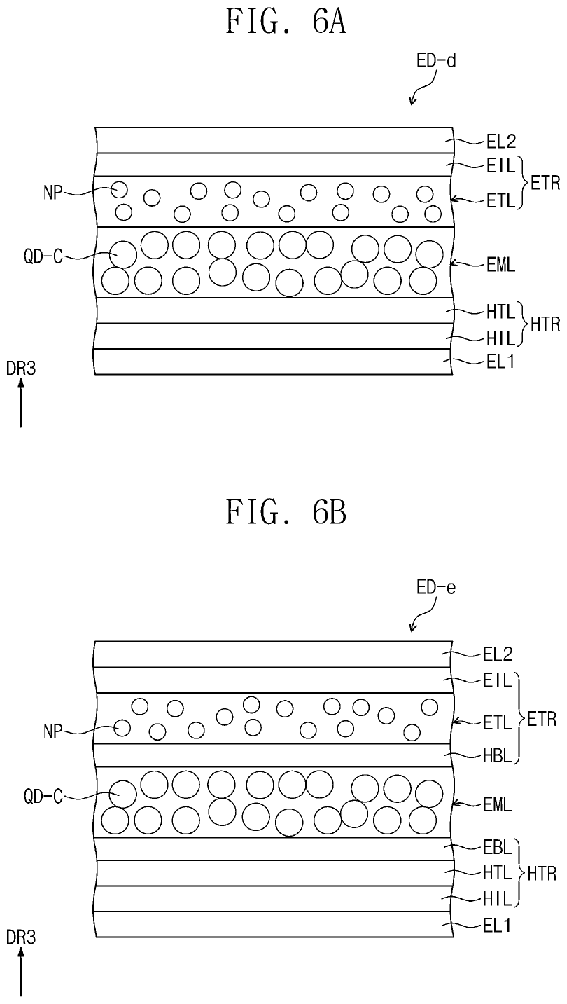

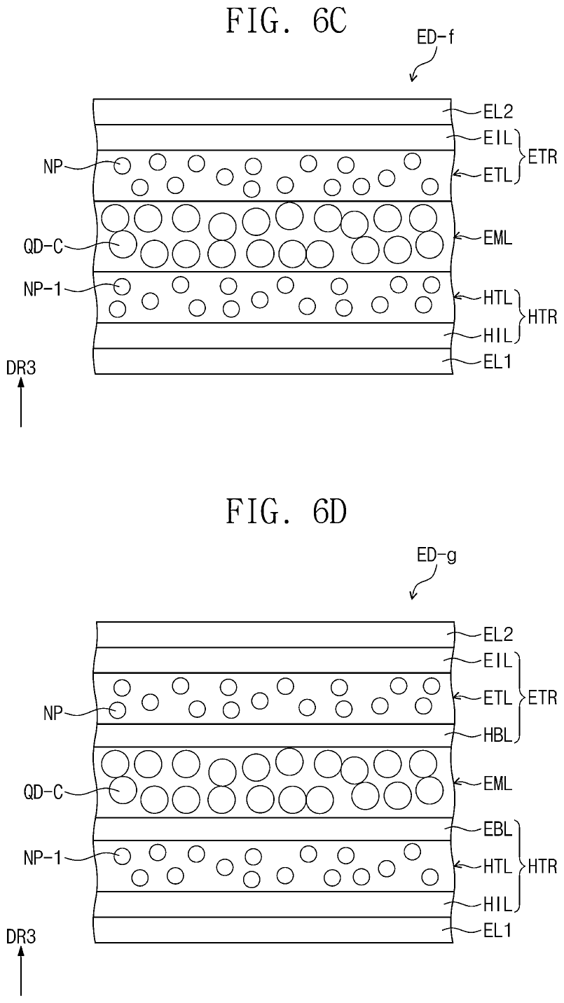

In an embodiment, at least one of the electron transport regions ETR-1, ETR-2, and ETR-3 and the hole transport regions HTR-1, HTR-2, and HTR-3 may include metal nanoparticles NP and NP-1 (see FIG. 5A to FIG. 6D), which will be described later. In an embodiment, the metal nanoparticles NP and NP-1 (see FIG. 5A to FIG. 6D) may include a core MC (see FIG. 8) and a ligand LD (see FIG. 8) bonded to the core MC (see FIG. 8).

In an embodiment, the core MC (see FIG. 8) may include a metal oxide, and the ligand LD (see FIG. 8) may include an acidic functional group, a basic functional group, or an ultraviolet-reactive functional group. The ligand including an acidic functional group, a basic functional group, or an ultraviolet-reactive functional group may have improved charge transport and/or charge injection characteristics to thereby contribute to a decrease in driving voltage and improvement in efficiency of the light-emitting elements ED-1, ED-2, and ED-3. The display devices DD and DD-1 to DD-3 including the light-emitting elements ED-1, ED-2, and ED-3 that contain the ligand including an acidic functional group, a basic functional group, or an ultraviolet-reactive functional group may exhibit excellent display efficiency. The metal nanoparticles NP and NP-1 (see FIG. 5A to FIG. 6D) will be described later in more detail.

The electron transport regions ETR-1, ETR-2, and ETR-3 of the first to third light-emitting elements ED-1, ED-2, and ED-3 may each be disposed in the openings OH to thereby be distinct from each other. The first light-emitting element ED-1 may include a first electron transport region ETR-1, the second light-emitting element ED-2 may include a second electron transport region ETR-2, and the third light-emitting element ED-3 may include a third electron transport region ETR-3.

The first to third electron transport regions ETR-1, ETR-2, and ETR-3 may each be a layer consisting of a single material, a layer including different materials, or a structure including multiple layers including different materials. The first to third electron transport regions ETR-1, ETR-2, and ETR-3 may each independently have a thickness in a range of about 300 Å to about 1,500 Å. For example, the first to third electron transport regions ETR-1, ETR-2, and ETR-3 may each independently have a thickness in a range of about 1,000 Å to about 1,500 Å.

In embodiments, the first to third electron transport regions ETR-1, ETR-2, and ETR-3 may include electron injection materials of the related art and/or electron transport materials of the related art. For example, the first to third electron transport regions ETR-1, ETR-2, and ETR-3 may each include the metal nanoparticle NP (see FIG. 5A to FIG. 6D) according to an embodiment, and may each further include electron injection materials of the related art and/or electron transport materials of the related art. As another example, the electron transport regions ETR-1 and ETR-2 respectively adjacent to the emission layers EML-B and EML-G may each include the metal nanoparticle according to an embodiment, and the electron transport region ETR-3 adjacent to the emission layer EML-Ra including an organic emission material may include electron injection materials of the related art and/or electron transport materials of the related art. However, this is only an example, and embodiments are not limited thereto.

For example, the first to third electron transport regions ETR-1, ETR-2, and ETR-3 may each include an anthracene-based compound. As another example, the first to third electron transport regions ETR-1, ETR-2, and ETR-3 may each independently include tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), any combination thereof. As yet another example, the first to third electron transport regions ETR-1, ETR-2, and ETR-3 may each independently include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), etc.

The hole transport regions HTR-1, HTR-2, and HTR-3 of the first to third light-emitting elements ED-1, ED-2, and ED-3 may each be disposed in the openings OH to thereby be distinct from each other. The first light-emitting element ED-1 may include a first hole transport region HTR-1, the second light-emitting element ED-2 may include a second hole transport region HTR-2, and the third light-emitting element ED-3 may include a third hole transport region HTR-3.

The first to third hole transport regions HTR-1, HTR-2, and HTR-3 may each be a layer consisting of a single material, a layer including different materials, or a structure including multiple layers including different materials. The first to third hole transport regions HTR-1, HTR-2, and HTR-3 may each independently have a thickness in a range of, for example, about 50 Å to about 15,000 Å. For example, the first to third hole transport regions HTR-1, HTR-2, and HTR-3 may each independently have a thickness in a range of about 100 Å to about 10,000 Å, For example, the first to third hole transport regions HTR-1, HTR-2, and HTR-3 may each independently have a thickness in a range of about 100 Å to about 5,000 Å.

In embodiments, the first to third hole transport regions HTR-1, HTR-2, and HTR-3 may include hole injection materials of the related art and/or hole transport materials of the related art. For example, the first to third hole transport regions HTR-1, HTR-2, and HTR-3 may each include the metal nanoparticle NP-1 (see FIGS. 5C, 5D, 6D, and 6D) according to an embodiment, and may each further include hole injection materials of the related art and/or the hole transport materials of the related art. As another example, the hole transport regions HTR-1 and HTR-2 respectively adjacent to the emission layers EML-B and EML-G respectively including the quantum dots QD-C1 and QD-C2 may each include the metal nanoparticle according to an embodiment, and the hole transport region HTR-3 adjacent to the emission layer EML-Ra including an organic emission material may include hole injection materials of the related art and/or the hole transport materials of the related art. However, this is only an example, and embodiments are not limited thereto.

For example, the first to third hole transport regions HTR-1, HTR-2, and HTR-3 may each independently include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N, N-diphenylamino)triphenylamine (TDATA), 4,4′,4″-tris[N(2-naphthyl)-N-phenylamino]-triphenylamine (2-TNATA), poly(3,4-ethylenedioxythiophene)/poly (4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), polyether ketone containing triphenylamine (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

In embodiments, the first to third hole transport regions HTR-1, HTR-2, and HTR-3 may each independently include: carbazole-based derivatives such as N-phenylcarbazole and polyvinylcarbazole; fluorene-based derivatives; triphenylamine-based derivatives such as N,N′-bis(3-methylphenyl)-N,N′-diphenyl-[1,1′-biphenyl]-4,4′-diamine (TDN), 4,4′,4″-tris(N-carbazolyl)triphenylamine (TCTA); N,N′-di(naphthalene-1-yl)-N,N′-diplienyl-benzidine (NPB); (4,4′-cyclohexylidene bis[N,N-bis(4-methylphenyl)benzenamine](TAPC); 4,4′-bis[N,N′-(3-tolyl)amino]-3,3′-dimethylbiphenyl (HMTPD); 9-(4-tert-Butylphenyl)-3,6-bis(triphenylsilyl)-9H-carbazole (CzSi); 9-phenyl-9H-3,9′-bicarbazole (CCP); 1,3-bis(N-carbazolyl)benzene (mCP); 1,3-bis(1,8-dimethyl-9H-carbazol-9-yl)benzene (mDCP), etc.

The encapsulation layer TFE may include at least one inorganic film (hereinafter, referred to as an encapsulation inorganic film). In an embodiment, the encapsulation layer TFE may include at least one organic film (hereinafter, referred to as an encapsulation organic film).

The encapsulation inorganic film may protect the display element layer DP-EL from moisture and/or oxygen, and the encapsulation organic film may protect the display element layer DP-EL from foreign materials such as dust particles. The encapsulation inorganic film may include silicon nitride, silicon oxynitride, silicon oxide, titanium oxide, aluminum oxide, etc., but embodiments are not limited thereto. The encapsulation organic film may include an acrylate-based compound, an epoxy-based compound, etc. The encapsulation organic film may include a photopolymerizable organic material but embodiments are not limited thereto.

The optical layer PP includes a base substrate BL and a color filter layer CFL. The base substrate BL may provide a base surface on which a color filter layer CFL is disposed. The base substrate BL may be a glass substrate, a metal substrate, a plastic substrate, etc. However, embodiments are not limited thereto, and the base substrate BL may include an inorganic layer, an organic layer, or a composite material layer.

The color filter layer CFL may include first to third filters CF-B, CF-G, and CF-R. The first to third filters CF-B, CF-G, and CF-R may be disposed to respectively correspond to the first to third light-emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may be disposed to respectively correspond to the first to third emission regions PXA-B, PXA-G, and PXA-R.

The first to third filters CF-B, CF-G, and CF-R may each include a polymeric photosensitive resin and a pigment or dye. The first filter CF-B may include a blue pigment or a blue dye, the second filter CF-G may include a green pigment or a green dye, and the third filter CF-R may include a red pigment or a red dye. However, embodiments are not limited thereto, and the first filter CF-B may not include a pigment or dye. The first filter CF-B may include a polymer photosensitive resin and may not include a pigment or dye. The first filter CF-B may be transparent. The first filter CF-B may be formed of a transparent photosensitive resin.

The color filter layer CFL may further include a buffer layer BFL. For example, the buffer layer BFL may serve as a protection layer for the first to third filters CF-B, CF-G, and CF-R. The buffer layer BFL may be an inorganic layer that includes at least one inorganic material selected from silicon nitride, silicon oxide, and silicon oxynitride. The buffer layer BFL may be formed of a single layer or of multiple layers.

In an embodiment, the second filter CF-G and the third filter CF-R may each be a yellow filter. The second filter CF-G and the third filter CF-R may be provided as a single unit without being separated from each other.

Although not shown in the drawings, the color filter layer CFL may further include a light-blocking part (not shown). The light-blocking part (not shown) may be a black matrix. The light-blocking part (not shown) may include organic light-blocking materials or inorganic light-blocking materials, each including a black pigment or a black dye. The light-blocking part (not shown) may prevent light leakage and may separate the boundaries between adjacent filters CF-B, CF-G, and CF-R.

FIG. 4B to FIG. 4D are respectively a schematic cross-sectional view of display devices DD-1, DD-2, and DD-3 according to embodiments. In the descriptions of FIG. 4B to 4D, the features that have been described with respect to FIG. 1 to FIG. 4A will not be explained again, and the differing features will be described.

In comparison to the display device DD illustrated in FIG. 4A, the display device DD-1 illustrated in FIG. 4B is different, at least in that the second emission layer EML-Ga includes a different material. In FIG. 4A, the second emission layer EML-G includes the second quantum dot QD-C2, and in FIG. 4B, the second emission layer EML-Ga includes an organic emission material. The second emission layer EML-Ga may include a first organic emission material that emits green light. For example, the second emission layer EML-Ga may include a host material and a dopant material. In FIG. 4B, the third emission layer EML-Ra may include a second organic emission material that emits red light.

In comparison to the display device DD illustrated in FIG. 4A, the display device DD-2 illustrated in FIG. 4C is different at least in that the third emission layer EML-R includes a different material. In FIG. 4C, the third emission layer EML-R includes a third quantum dot QD-C3. The third quantum dot QD-C3 may emit red light. The first emission layer EML-B may include the first quantum dot QD-C1 that emits blue light, and the second emission layer EML-G may include the second quantum dot QD-C2 that emits green light.

The third quantum dot QD-C3 may be stacked to form at least one layer. FIG. 4C shows, as an example, that the third quantum dots QD-C3, which has a circular-shaped cross-section, are arranged to thereby form approximately two layers, but embodiments are not limited thereto. For example, an arrangement of the third quantum dot QD-C3 may differ depending on a thickness of the third emission layer EML-R, depending on a shape of the third quantum dot QD-C3 in the third emission layer EML-R, depending on an average diameter of the third quantum dot QD-C3, etc. For example, the third quantum dots QD-C3 may be arranged to have a single-layered configuration, or may be arranged to a multilayered configuration, such as two layers or three layers.

In FIG. 4C, it is shown that the first to third quantum dots QD-C1, QD-C2, and QD-C3 each have a substantially similar diameter, but embodiments are not limited thereto. For example, in an embodiment, the first to third quantum dots QD-C1, QD-C2, and QD-C3 may have a different diameter from each other.

In comparison to the display device DD illustrated in FIG. 4A, the display device DD-3 illustrated in FIG. 4D is different at least in that the hole transport regions HTR-1, HTR-2, and HTR-3 and the electron transport regions ETR-1, ETR-2, and ETR-3 are disposed in relatively different positions, and is different at least in that the third emission layer EML-R includes a different material. In FIG. 4A, the electron transport regions ETR-1, ETR-2, and ETR-3 are illustrated to be respectively disposed below the emission layers EML-B, EML-G, and EML-R, and in FIG. 4B, the electron transport regions ETR-1, ETR-2, and ETR-3 are illustrated to be respectively disposed on the emission layers EML-B, EML-G, and EML-R.

Referring to FIG. 4D, the first to third light-emitting elements ED-1, ED-2, and ED-3 may include a first electrode EL1, hole transport regions HTR-1, HTR-2, and HTR-3 disposed on the first electrode EL1, emission layers EML-B, EML-G, and EML-R respectively disposed on the hole transport regions HTR-1, HTR-2, and HTR-3, electron transport regions ETR-1, ETR-2, and ETR-3 respectively disposed on the emission layers EML-B, EML-G, and EML-R, and a second electrode EL2 disposed on the electron transport regions ETR-1, ETR-2, and ETR-3.

The third emission layer EML-R may include the third quantum dot QD-C3. The third quantum dot QD-C3 may emit red light. The third quantum dot QD-C3 may be the same as or substantially similar to the third quantum dot QD-C3 as described with respect to FIG. 4C.

FIG. 5A to FIG. 6D are respectively a schematic cross-sectional view of light-emitting elements ED and ED-a to ED-g according to embodiments. At least one of the first to third light-emitting elements ED-1, ED-2, and ED-3 illustrated in FIG. 4A to FIG. 4C may have a structure according to one of the light-emitting elements ED, ED-a, ED-b, and ED-c, as illustrated in FIG. 5A to FIG. 5D. At least one of the first to third light-emitting elements ED-1, ED-2, and ED-3 illustrated in FIG. 4D, may have a structure according to one of the light-emitting elements ED-d, ED-e, ED-f, and ED-g, as illustrated in FIG. 6A to FIG. 6D.

FIG. 5A to FIG. 5D respectively show the light-emitting elements ED, ED-a, ED-b, and ED-c, each including the electron transport region ETR disposed between the first electrode EL1 and the emission layer EML, and the hole transport region HTR disposed between the emission layer EML and the second electrode EL2. In contrast, FIG. 6A to FIG. 6D respectively show the light-emitting elements ED-d, ED-e, ED-f, and ED-g, each including the hole transport region HTR disposed between the first electrode EL1 and the emission layer EML, and the electron transport region ETR disposed between the emission layer EML and the second electrode EL2.

Referring to FIG. 5A to FIG. 6D, the electron transport region ETR may include at least an electron injection layer EIL and an electron transport layer ETL. Referring to FIG. 5A to FIG. 5D, the electron injection layer EIL may be disposed on the first electrode EL1, and the electron transport layer ETL may be disposed on the electron injection layer EIL. Referring to FIG. 5B and FIG. 5D, the electron transport region ETR may further include a hole blocking layer HBL disposed between the electron transport layer ETL and the emission layer EML.

Referring to FIG. 6A to FIG. 6D, the electron transport layer ETL may be disposed on the emission layer EML, and the electron injection layer EIL may be disposed on the electron transport layer ETL. Referring to FIG. 6B and FIG. 6D, the electron transport region ETR may further include a hole blocking layer HBL disposed between the emission layer EML and the electron transport layer ETL. Although not shown in FIG. 5A to 6D, in an embodiment, the electron injection layer EIL may be omitted.

At least one of the electron injection layer EIL, the electron transport layer ETL, and the hole blocking layer HBL may include the metal nanoparticle NP according to an embodiment. For example, at least one of the electron injection layer EIL and the electron transport layer ETL may include the metal nanoparticle according to an embodiment. In FIG. 5A to FIG. 6D, the electron transport layer ETL is shown to include the metal nanoparticle NP according to an embodiment, but embodiments are not limited thereto.

Referring to FIG. 5A to FIG. 6D, the hole transport region HTR may include a hole injection layer HIL and a hole transport layer HTL. Referring to FIG. 5A to FIG. 5D, the hole transport layer HTL may be disposed on the emission layer EML, and the hole injection layer HIL may be disposed on the hole transport layer HTL. Referring to FIG. 5B and FIG. 5D, the hole transport region HTR may further include an electron blocking layer EBL disposed between the emission layer EML and the hole transport layer HTL. Referring to FIG. 6A to FIG. 6D, the hole injection layer HIL may be disposed on the first electrode EL1, and the hole transport layer HTL may be disposed on the hole injection layer HIL. Referring to FIG. 6B and FIG. 6D, the hole transport region HTR may further include an electron blocking layer EBL disposed between the hole transport layer HTL and the emission layer EML.

At least one of the hole injection layer HIL, the hole transport layer HTL, and the electron blocking layer EBL may include a metal nanoparticle NP-1 according to an embodiment. For example, at least one of the hole injection layer HIL and the hole transport layer HTL may include the metal nanoparticle NP-1 according to an embodiment. In FIGS. 5C, 5D, 6C, and 6D, the hole transport layer HTL is shown to include the metal nanoparticle NP-1 according to an embodiment, but embodiments are not limited thereto.

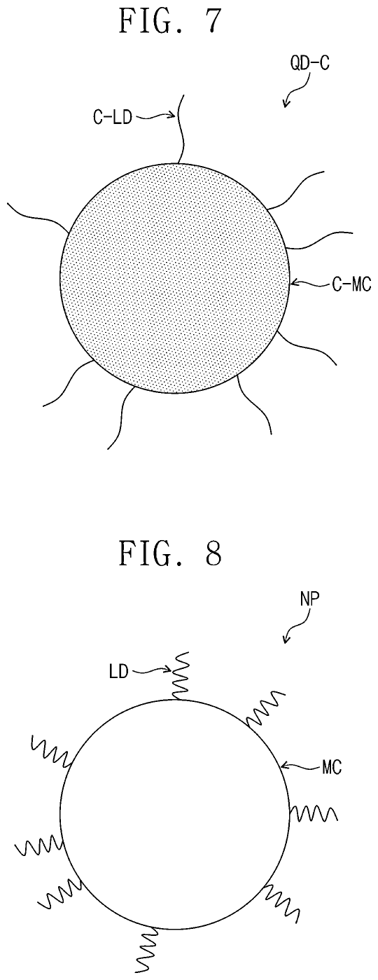

As shown in FIG. 5A to FIG. 6D, the emission layer EML may include the quantum dot QD-C. FIG. 7 is a schematic cross-sectional view of the quantum dot QD-C. The first to third quantum dots QD-C1, QD-C2, and QD-C3 as illustrated in FIG. 4A to FIG. 4D may be the same as or substantially similar to the quantum dot QD-C as explained in the following descriptions.

Referring to FIG. 7, the quantum dot QD-C may include a core part C-MC, and a ligand part C-LD bonded to the core part C-MC. The ligand part C-LD of the quantum dot QD-C may include an acidic functional group according to an embodiment or a basic functional group according to an embodiment. The ligand part C-LD may include a same functional group as the ligand LD of the metal nanoparticle NP (see FIG. 8) according to an embodiment. In another embodiment, the ligand part C-LD may include a functional group that is different from the ligand LD of the metal nanoparticle NP (see FIG. 8) according to an embodiment. For example, the ligand part C-LD of the quantum dot QD-C and the ligand LD of the metal nanoparticle NP (see FIG. 8) may each independently include an acidic functional group or a basic functional group. As another example, the ligand part C-LD of the quantum dot QD-C may include an acidic functional group and the ligand LD of the metal nanoparticle NP (see FIG. 8) may include a basic functional group or an ultraviolet-reactive functional group. As yet another example, the ligand LD of the metal nanoparticle NP (see FIG. 8) may include one of an acidic functional group, a basic functional group, and an ultraviolet-reactive functional group, and the ligand part C-LD of the quantum dot QD-C may include a ligand that does not acidic functional group, a basic functional group, or ultraviolet-reactive functional group. However, this is only an example, and the ligand part C-LD of the quantum dot QD-C is not limited thereto.

The core part C-MC of the quantum dot QD-C may include an inorganic compound. The quantum dot QD-C may include a crystal of a semiconductor compound. The quantum dot QD-C may emit light having various emission wavelengths depending on a size of the crystal. A diameter of the quantum dot QD-C may be, for example, in a range of about 1 nm to about 10 nm.

The quantum dot QD-C may be synthesized by a wet chemical process, a metal organic chemical vapor deposition process, a molecular beam epitaxy process, or a similar process. The wet chemical process is a method in which an organic solvent and a precursor material are mixed to grow a crystal of a quantum dot QD-C particle. When the crystal is grown, the organic solvent may naturally serve as a dispersant that is coordinated to a surface of a quantum dot QD-C crystal and may control the growth of the crystal. Therefore, the wet chemical process may control the growth of the quantum dot QD-C particles through a simpler and more cost-effective process than a vapor deposition method such as metal organic chemical vapor deposition (MOCVD) or molecular beam epitaxy (MBE).

In embodiments, the quantum dot QD-C may include a Group II-VI semiconductor compound, a Group I-II-VI semiconductor compound, a Group II-IV-VI compound, a Group I-II-IV-VI semiconductor compound, a Group III-V semiconductor compound, a Group III-VI semiconductor compound, a Group I-III-VI semiconductor compound, a IV-VI semiconductor compound, a Group II-IV-V semiconductor compound, a Group IV element or compound, or any combination thereof. In the specification, the term “Group” refers to a group of the IUPAC periodic table.

Examples of a Group II-VI semiconductor compound may include: binary compounds such as CdS, CdSe, CdTe, ZnS, ZnSe, ZnTe, ZnO, HgS, HgSe, HgTe, MgSe, and MgS; ternary compounds such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS; quaternary compounds such as CdZnSeS, CdZnSeTe, CdZnSTe, CdHgSeS, CdHgSeTe, CdHgSTe, HgZnSeS, HgZnSeTe, and HgZnSTe; and any combination thereof.

In an embodiment, a Group II-VI semiconductor compound may further include a Group I element and/or a Group IV element. Examples of a Group I-II-VI compound may include CuSnS or CuZnS. Examples of a Group II-IV-VI compound may include ZnSnS and the like. Examples of a Group I-II-IV-VI compound may include quaternary compounds such as Cu₂ZnSnS₂, Cu₂ZnSnS₄, Cu₂ZnSnSe₄, Ag₂ZnSnS₂, and any combination thereof.

Examples of a Group III-V semiconductor compound may include: binary compounds such as GaN, GaP, GaAs, GaSb, AlN, AlP, AlAs, AlSb, InN, InP, InAs, and InSb; ternary compounds such as GaNP, GaNAs, GaNSb, GaPAs, GaPSb, AlNP, AlNAs, AlNSb, AlPAs, AlPSb, InGaP, InNP, InAIP, InNAs, InNSb, InPAs, and InPSb; quaternary compounds such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb; and any combination thereof. In an embodiment, a Group III-V semiconductor compound may further include a Group II element. Examples of a Group III-V semiconductor compound further including a Group II element may include InZnP, InGaZnP, InAlZnP, etc.

Examples of a Group III-VI semiconductor compound may include: binary compounds such as GaS, Ga₂S₃, GaSe, Ga₂Se₃, GaTe, InS, InSe, In₂Se₃, and InTe; ternary compounds such as InGaS₃, and InGaSe₃; or any combination thereof.

Examples of a Group I-III-VI semiconductor compound may include: ternary compounds such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂; quaternary compounds such as AgInGaS₂, and AgInGaSe₂; and any combination thereof.

Examples of a Group IV-VI semiconductor compound may include: binary compounds such as SnS, SnSe, SnTe, PbS, PbSe, and PbTe; ternary compounds such as SnSeS, SnSeTe, SnSTe, PbSeS, PbSeTe, PbSTe, SnPbS, SnPbSe, and SnPbTe; quaternary compounds such as SnPbSSe, SnPbSeTe, and SnPbSTe; and any combination thereof.

Examples of a Group II-IV-V semiconductor compound may include: a ternary compound such as ZnSnP, ZnSnP2, ZnSnAs2, ZnGeP2, ZnGeAs2, CdSnP2, CdGeP2; and any combination thereof.

Examples of a Group IV element or compound may include: a single element material such as Si and Ge; a binary compound such as SiC, and SiGe; and any combination thereof.

Each element included in a compound such as a binary compound, a ternary compound, or a quaternary compound may be present in a particle at a uniform concentration or at a non-uniform concentration. For example, a formula may indicate the elements that are included in a compound, but an elemental ratio in the compound may vary. For example, AgInGaS₂ may indicate AgInₓGa₁₋ₓS₂ (where x is a real number between 0 and 1).

In an embodiment, the quantum dot QD-C may have a single structure in which the concentration of each element in the quantum dot QD-C is uniform. In another embodiment, the core part C-MC of the quantum dot QD-C may have a core-shell structure. For example, in the quantum dot QD-C, a material included in the core may be different from a material included in the shell.

The shell of the quantum dot QD-C may serve as a protection layer that prevents chemical alteration of the core to maintain semiconductor properties and/or may serve as a charging layer that imparts the quantum dot with electrophoretic properties. The shell may be a single layer or a multilayer. A quantum dot that has a core/shell structure may have a concentration gradient in which the concentration of an element that is present in the shell decreases toward the core part C-MC.

Examples of a shell of the quantum dot QD-C may include a metal oxide, a non-metal oxide, a semiconductor compound, and any combination thereof. Examples of a metal oxide or a non-metal oxide may include: binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO; ternary compounds such as MgAl₂O₄, CoFe₂O₄, NiFe₂O₄, and CoMn₂O₄; and any combination thereof. Examples of a semiconductor compound, as described in the specification, may include: a Group III-VI semiconductor compound; a Group II-VI semiconductor compound; a Group III-V semiconductor compound; a Group III-VI semiconductor compound; a Group I-II-VI semiconductor compound; a Group IV-VI semiconductor compound; and any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, or any combination thereof.

The quantum dot QD-C may have a full width at half maximum (FWHM) of an emission spectrum equal to or less than about 45 nm. For example, the quantum dot QD-C may have a FWHM of an emission spectrum equal to or less than about 40 nm. For example, the quantum dot QD-C may have a FWHM of an emission spectrum equal to or less than about 30 nm. When the FWHM of the quantum dot QD-C falls within any of the above ranges, color purity or color reproducibility may be improved. Light emitted through the quantum dot QD-C may be emitted in all directions, so that an optical viewing angle may be improved. The quantum dot QD-C may have any form or shape that is used in the related art. For example, the quantum dot QD-C may have a spherical shape, a pyramidal shape, a multi-arm shape, or a cubic shape, or the quantum dot QD-C may be in the form of nanoparticles, nanotubes, nanowires, nanofibers, nanoplatelets, etc.

An energy band gap may be adjusted by adjusting a size of the quantum dot QD-C or by adjusting an elemental ratio of a compound in the quantum dot QD-C, so that light of various wavelengths may be emitted from the emission layer EML including the quantum dot QD-C. Therefore, when the quantum dot QD-C as described herein (quantum dots having different sizes or having different elemental ratios) is used, light-emitting elements ED and ED-a to ED-g that emit light of various wavelengths may be achieved. For example, adjustments in sizes of the quantum dot QD-C and in elemental ratios of a compound in the quantum dot QD-C may be selected so that red light, green light, and/or blue light may be emitted. In an embodiment, the quantum dots QD-C may be configured to emit white light by combining various colors of light.

The metal nanoparticle NP (see FIG. 5A to FIG. 6D) included in the electron transport region ETR and the metal nanoparticle NP-1 (see FIGS. 5C, 5D, 6C, and 6D) included in the hole transport region HTR may be the same as or different from each other. The metal nanoparticle NP (see FIG. 5A to FIG. 6D) included in the electron transport region ETR and the metal nanoparticle NP-1 (see FIGS. 5C, 5D, 6C, and 6D) included in the hole transport region HTR may each be the same as or substantially similar to the metal nanoparticle NP as explained in the following descriptions.

FIG. 8 is a schematic cross-sectional view of the metal nanoparticle NP according to an embodiment. Referring to FIG. 8, the metal nanoparticle NP may include a core MC, and a ligand LD bonded to the core MC. The core MC may include a metal oxide. In embodiments, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or the metal oxide may be represented by Formula M-1.

Zn_{q}Me_{(1-q)}O [Formula M-1]

In Formula M-1, q may be a real number from 0 to 0.5. In Formula M-1, Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

For example, the core MC may include any one of zinc oxide (ZnO), zinc magnesium oxide (ZMO), and molybdenum trioxide (MoO₃). The electron transport region ETR may include the metal nanoparticle NP according to an embodiment, and the core MC of the metal nanoparticle NP may include ZnO or ZMO. The hole transport region HTR may include the metal nanoparticle NP according to an embodiment, and the core MC of the metal nanoparticle NP may include MoO₃. However, these are only examples, and embodiments are not limited thereto.

In an embodiment, the ligand LD may include an acidic functional group, a basic functional group, or an ultraviolet-reactive functional group. In an embodiment, the ultraviolet-reactive functional group may shrink or may expand when ultraviolet light is provided. Since the ultraviolet-reactive functional group may shrink or may expand when ultraviolet light is provided, the length and/or the volume of the functional group may vary.

In an embodiment, the ultraviolet-reactive functional group may include at least one of a spiropyran group and a merocyanine group. In an embodiment, the ligand LD including the ultraviolet-reactive functional group may be derived from at least one compound selected from Compound Group 1. In Compound Group 1, Compound L-C1 represents a spiropyran compound, and Compound L-C2 represents a merocyanine compound. When ultraviolet light is provided to the spiropyran compound, the bonds of the compound change, and thus the compound may become a merocyanine compound. When ultraviolet light is provided to the merocyanine compound, the bonds of the compound change, and thus the compound may become a spiropyran compound.

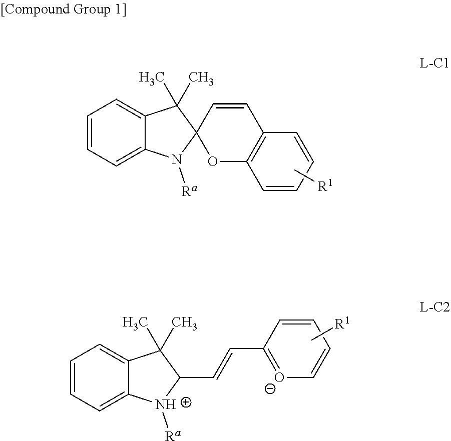

In Compound Group 1, R^{a} may be a substituted or unsubstituted alkyl group having 1 to 20 carbons. In Compound Group 1, R¹ may be a hydrogen atom, a deuterium atom, a halogen atom, a substituted or unsubstituted alkyl group having 1 to 20 carbons, a substituted or unsubstituted aryl group having 6 to 30 ring-forming carbons, or a substituted or unsubstituted heteroaryl group having 2 to 30 ring-forming carbons.

When the ligand LD includes Compound L-C1, a nitrogen atom (N), which is a ring-forming atom of a pentagonal ring, may be a position at which a bond to the core MC is formed. The ligand may be bonded to the core MC via an unshared electron pair of the nitrogen atom (N). When the ligand LD includes Compound L-C2, oxygen anion bonded to a benzene ring may be a position at which a bond the core MC is formed. The ligand may be bonded to the core MC via an unshared electron pair of the oxygen anion.

The acidic functional group may be a functional group that reacts with a basic material, and may shrink or may expand when the basic material is provided. The acidic functional group may shrink or may expand when the basic material is provided, and thus the length and/or the volume of the acidic functional group may vary.

In an embodiment, the acidic functional group may include at least one of a carboxylic acid group, a phosphoric acid group, a sulfonic acid group, an amino acid group, and a boronic acid group. The acidic functional group may include a hydroxy (—OH) group bonded to a carbon atom. When the ligand LD includes an acidic functional group, a hydrogen atom may be released from the hydroxy group, and an oxygen atom may be bonded to the core MC. In an embodiment, the ligand LD including the acidic functional group may be derived from at least one of acrylic acid (AAc), methacrylic acid (MAAc), ethylacrylic acid (EAAc), propylacrylic acid (PAAc), 4-vinylbenzoic acid (VBA), itaconic acid (IA), ethylene glycol acrylate phosphate (EGAP), vinylphosphonic acid (VPA), ethylene glycol methacrylate phosphate (EGMP), 4-vinyl-benzyl phosphonic acid (VBPA), vinylsulfonic acid (VSA), 4-styrenesulfonic acid (SSA), 2-acrylamido-2-methylpropane sulfonic acid (AMPS), 3-sulfopropyl methacrylate potassium salt (KSPMA), aspartic acid (ASA), L-glutamic acid (LGA), histidine (HIS), vinylphenyl boronic acid (VPBA), and 3-acrylamidophenyl boronic acid (AAPBA). For example, the ligand LD including an acidic functional group may be derived from at least one compound selected from Compound Group 2.

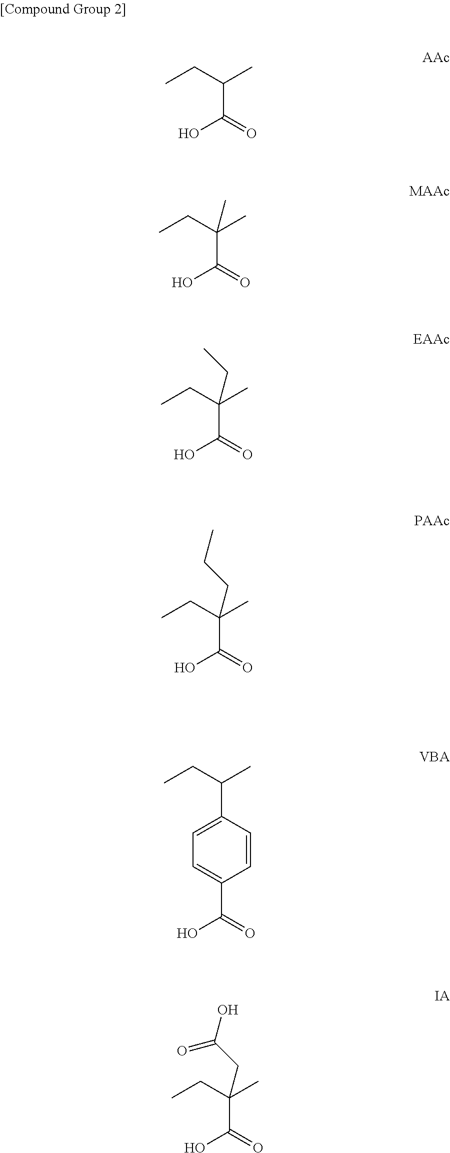

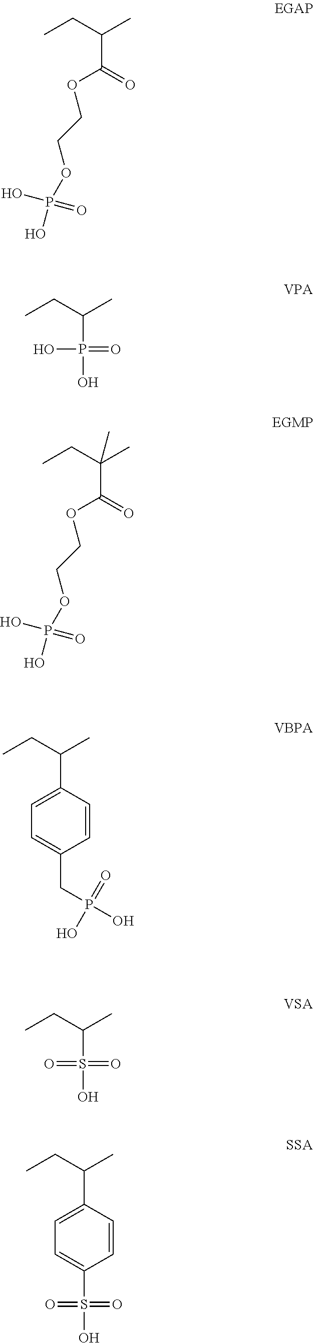

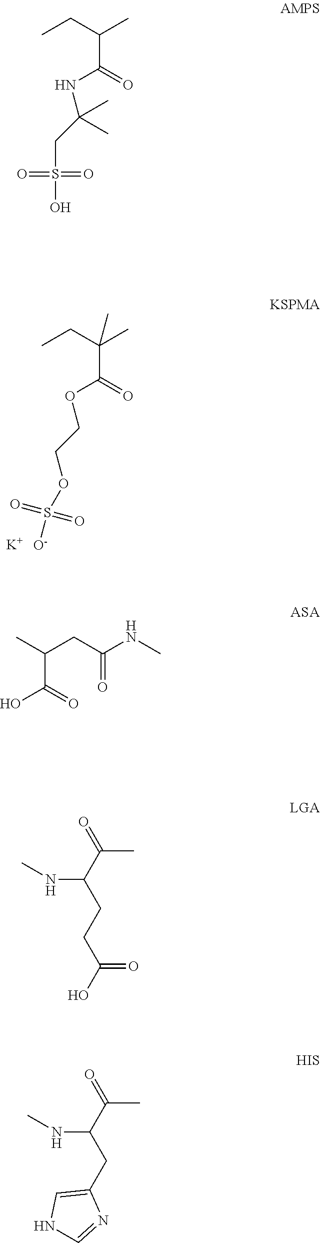

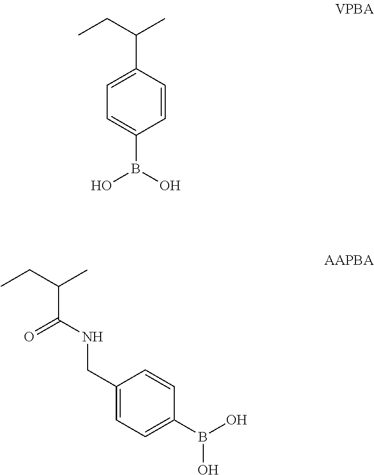 [SMILES: CCC(C)c1ccc(B(O)O)cc1 ; CCC(C)C(=O)NCc1ccc(B(O)O)cc1]

The basic functional group may be a functional group that reacts with an acidic material, and may shrink or may expand when the acidic material is provided. The basic functional group may shrink or may expand when the acidic material is provided, and thus the length and/or the volume of the basic functional group may vary. In an embodiment, the basic functional group may include at least one of an amine group, a morpholino group, a pyrrolidine group, a piperazine group, a pyridine group, and an imidazole group. The basic functional group may include a nitrogen atom bonded to a carbon atom. The nitrogen atom may include an unshared electron pair, and the ligand LD including the basic functional group may be bonded to the core MC via the unshared electron pair.

In an embodiment, the ligand LD including the basic functional group may be derived from at least one of (2-dimethylamino)ethyl methacrylate (DMA), (2-diethylamino)ethyl methacrylate (DEA), (2-dipropylamino)ethyl methacrylate DPAEMA), (2-diisopropylamino)ethyl methacrylate (DPA), N-(3-(dimethylamino)-propyl)methacrylamide (DMAPMAm), (2-dimethylamino)ethyl acrylate (DMAEA), 2-(tert-butylamino)ethyl methacrylate (tBAEMA), N,N-dimethylvinylbenzylamine, N,N-diethylvinylbenzylamine, N,N-dipropylvinylbenzylamine, (2-diethylamino)ethyl acrylamide (DEAm), (2-N-morpholino)ethyl methacrylate (MEMA), acryloylmorpholine (AM), (2-N-morpholino)ethyl methacrylamide (MEMAm), N-ethylpyrrolidine methacrylate (EPyM), N-acryloyl-N′-methyl piperazine, N-acryloyl-N′-ethyl piperazine, N-acryloyl-N′-propyl piperazine, 4-vinylpyridine (4VP), 2-vinylpyridine (2VP), N-vinylimidazole (VI), 6-(1H-imidazol-1-yl)hexyl-methacrylate (imHeMA), poly(propylenimine) dendrimer (PPI), poly(ethylenimine) dendrimer (PEI), and poly(amidoamine) dendrimer (PAMAM). For example, the ligand LD including the basic functional group may be derived from at least one compound selected from Compound Group 3.

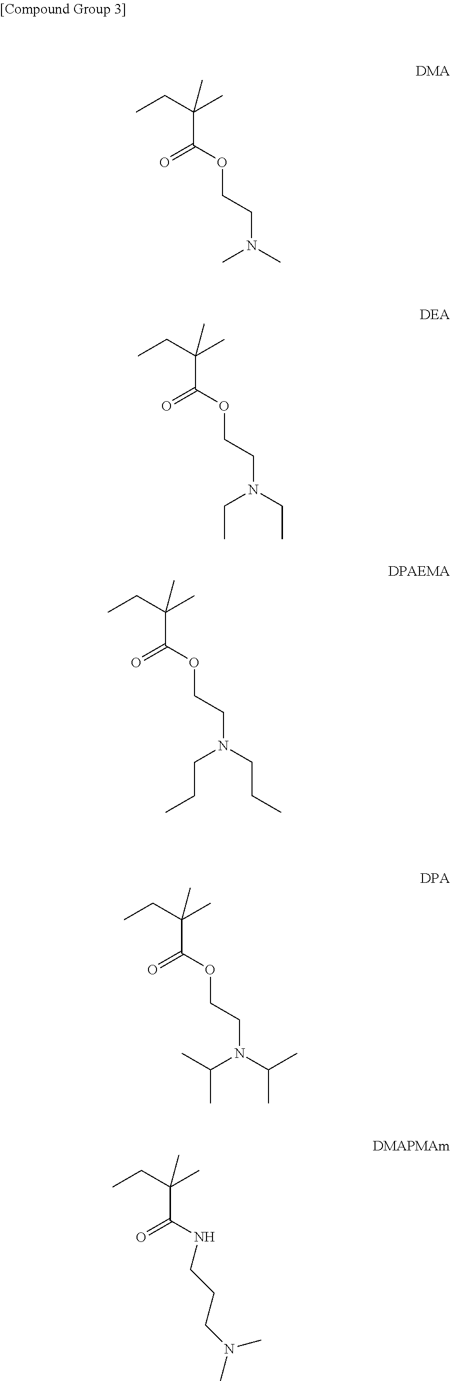

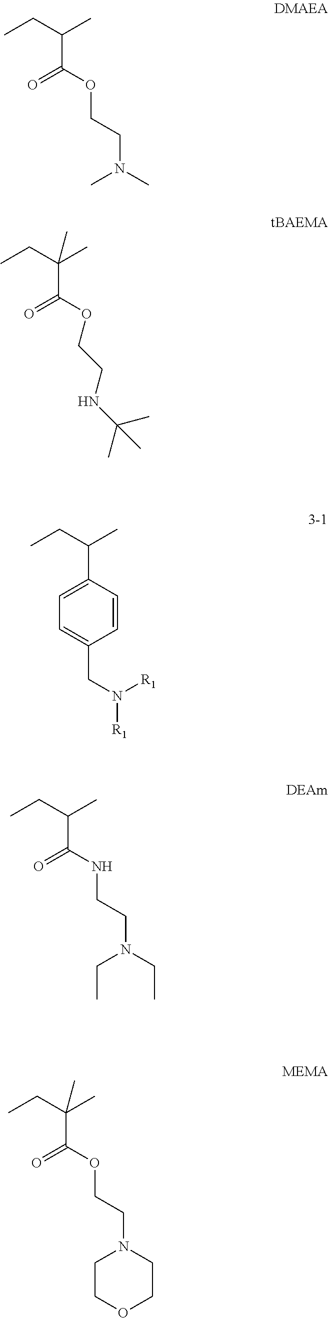

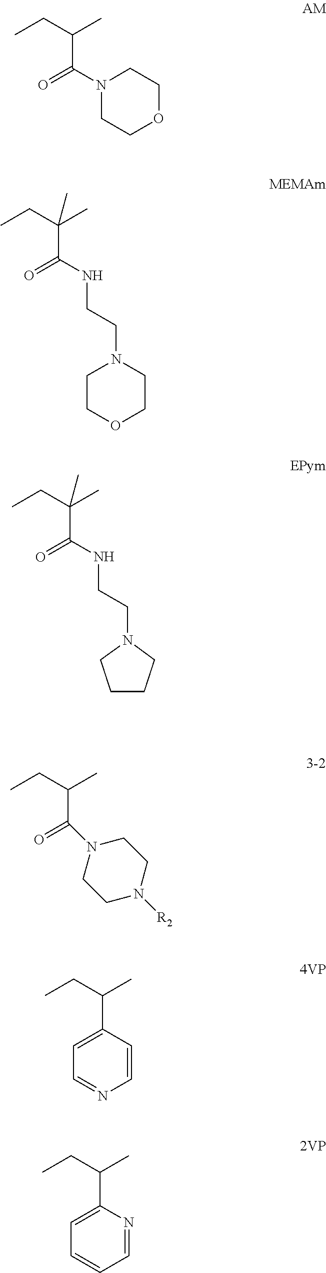

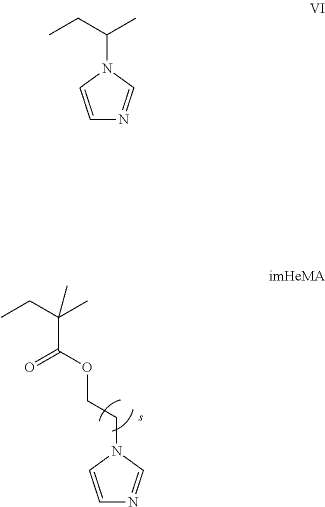

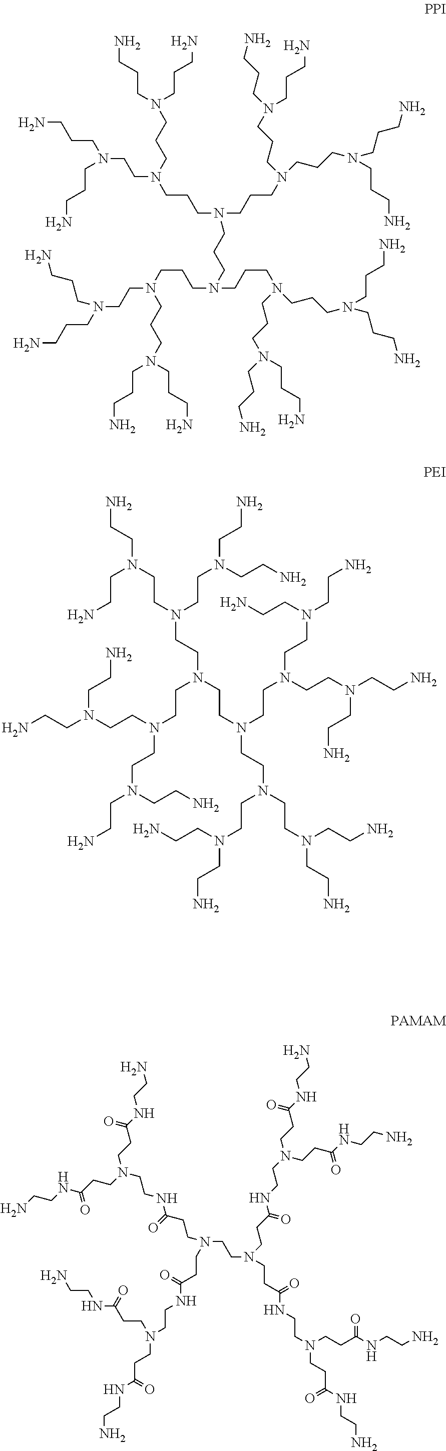 [SMILES: NCCCN(CCCN)CCCN(CCCN(CCCN)CCCN)CCCN(CCCN(CCCN(CCCN(CCCN)CCCN)CCCN(CCCN)CCCN)CCCN(CCCN(CCCN)CCCN)CCN(CCCN)CCCN)CCCN(CCCN(CCCN)CCCN)CCN(CCCN)CCCN ; NCCN(CCN)CCN(CCN(CCN)CCN)CCN(CCN(CCN(CCN)CCN)CCN(CCN)CCN)CCN(CCN(CCN(CCN)CCN)CCN(CCN)CCN)CCN(CCN(CCN)CCN)CCN(CCN)CCN ; NCCNC(=O)CCN(CCNC(=O)CCN(CCC(=O)NCCN(CCC(=O)NCCN)CCC(=O)NCCN)CCN(CCC(=O)NCCN(CCC(=O)NCCN)CCC(=O)NCCN)CCC(=O)NCCN(CCC(=O)NCCN)CCC(=O)NCCN)CCC(=O)NCCN]

In Compound Group 3, R₁ and R₂ may each independently be —CH₃, —CH₂CH₃, or —CH₂CH₂CH₃. In Compound Group 3, Compound 3-1 may be N,N-dimethylvinylbenzylamine, N,N-diethylvinylbenzylamine, or N,N-dipropylvinylbenzylamine. In Compound Group 3, Compound 3-2 may be N-acryloyl-N′-methyl piperazine, N-acryloyl-N′-ethyl piperazine, or N-acryloyl-N′-propyl piperazine.

In a conventional metal nanoparticle, a core that includes a metal oxide may have defects such as an oxygen vacancy, and the oxygen vacancy may transfer charges or may trap charges. When such defects are excessive, charges may be trapped in the core. If charges are trapped in the core, then the charges may not be injected into the emission layer, and characteristics of the light-emitting element may deteriorate. Even when such defects are not excessive, charges may not be readily injected into the emission layer, and characteristics of the light-emitting element may deteriorate.

By contrast, according to an embodiment, in the metal nanoparticle NP including an acidic functional group, a basic functional group, or an ultraviolet-reactive functional group, defects may be adjusted, which leads to an improvement in charge transfer and/or injection characteristics. The acidic functional group, the basic functional group, and the ultraviolet-reactive functional group may each be a functional group that shrinks or expands when a basic material, an acidic material, and ultraviolet light are provided, respectively, to thereby adjust defects of the core MC. The ligand LD including an acidic functional group, a basic functional group, or an ultraviolet-reactive functional group, may shrink or may expand when a basic material, an acidic material, or ultraviolet light is provided, respectively. In an embodiment, when the ligand LD shrinks, a surface area of the core MC to which the ligand LD is bonded may increase, metal nanoparticles NP may aggregate, which may decrease the density of a layer containing the metal nanoparticles NP. When the density of the layer decreases, a traveling path of light between metal nanoparticles NP may increase in distance, which may improve the efficiency of the light-emitting element ED. In another embodiment, when the ligand LD expands, interfacial activity with an adjacent electrode (for example, the first electrode EL1 and/or the second electrode EL2) may increase, and characteristics that facilitate charge injection may be enhanced.

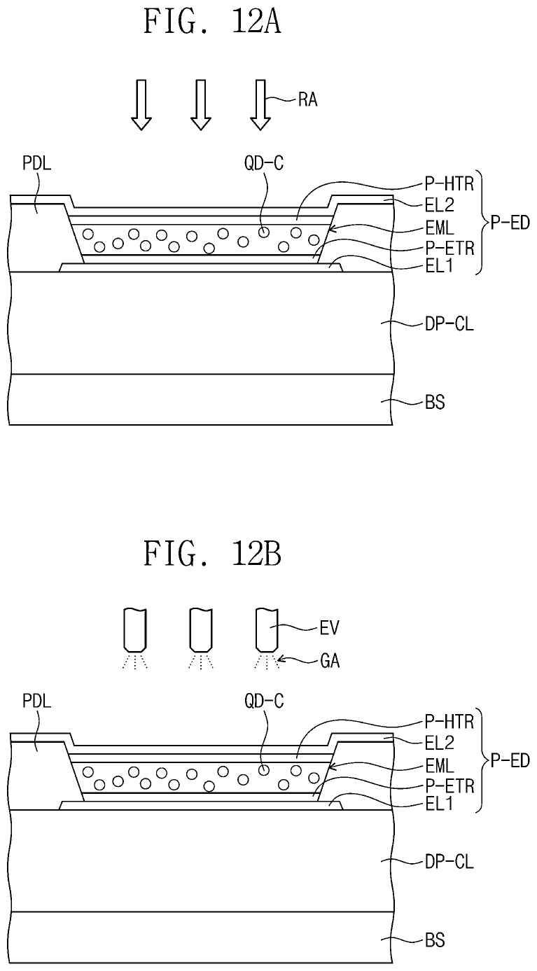

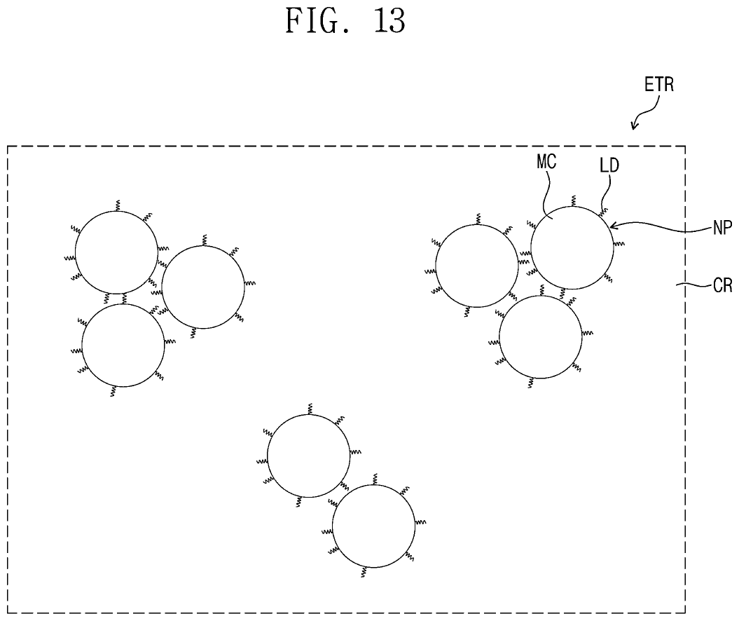

In an embodiment, when the electron transport region ETR includes the metal nanoparticle NP, the ligand LD of the metal nanoparticle NP may include an acidic functional group or an ultraviolet-reactive functional group. In a method of manufacturing the light-emitting element according to an embodiment, which will be described later, an electron transport region P-ETR (see FIG. 12B) of a preliminary light-emitting element P-ED (see FIG. 12B) may include a preliminary metal nanoparticle P-NP (see FIG. 11), and a basic material may be provided to the preliminary light-emitting element P-ED (see FIG. 12B) for negative aging. The acidic functional group included in the preliminary ligand P-LD (see FIG. 11) reacts with the basic material, and thus the preliminary ligand P-LD (see FIG. 11) may shrink or may expand. In another embodiment, ultraviolet light may be provided to the preliminary light-emitting element P-ED (see FIG. 12A), and the ultraviolet-reactive functional group included in the preliminary ligand P-LD (see FIG. 11) reacts to the ultraviolet light, and thus the preliminary ligand P-LD may shrink or may expand.

In an embodiment, when the hole transport region HTR includes a metal nanoparticle NP, the ligand LD of the metal nanoparticle NP may include a basic functional group or an ultraviolet-reactive functional group. In a method of manufacturing the light-emitting element according to an embodiment, which will be described later, a hole transport region P-HTR of the preliminary light-emitting element P-ED (see FIG. 12B) may include a preliminary metal nanoparticle P-NP (see FIG. 11), and an acidic material may be provided to the preliminary light-emitting element P-ED (see FIG. 12B) for positive aging. The basic functional group included in the preliminary ligand P-LD (see FIG. 11) reacts with the acidic material, and thus the preliminary ligand P-LD (see FIG. 11) may shrink or may expand.

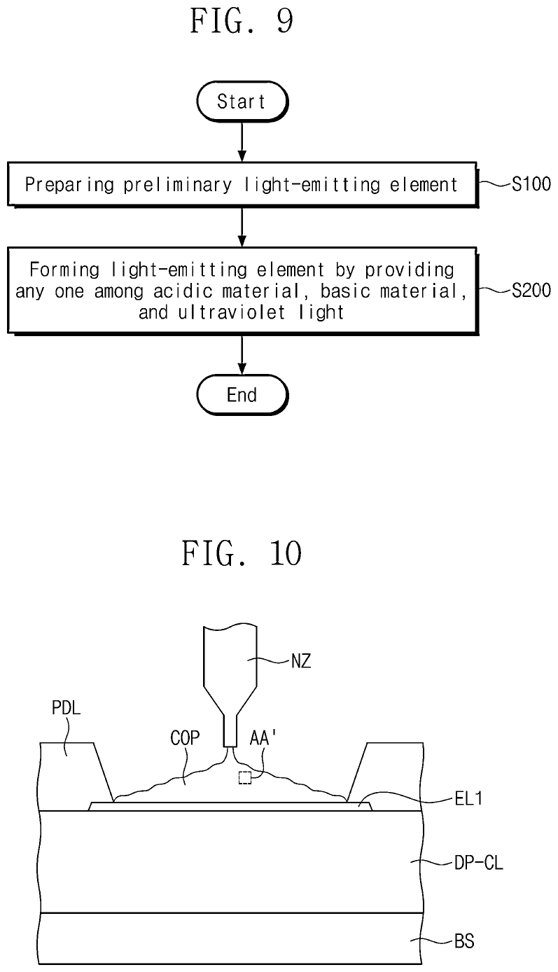

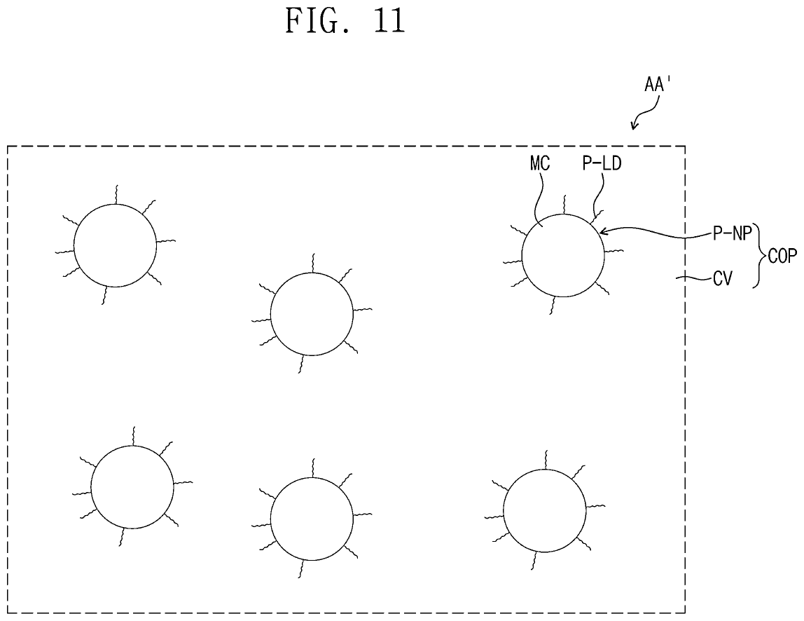

The light-emitting element according to an embodiment may be manufactured by a method according to an embodiment. FIG. 9 is a flow chart showing a method of manufacturing the light-emitting element according to an embodiment. FIG. 10 to FIG. 13 are each a schematic cross-sectional view showing steps of manufacturing the light-emitting element according to an embodiment. Hereinafter, for the descriptions of FIG. 9 to FIG. 13, the features that have been explained with reference to FIG. 1 to FIG. 8 will not be explained again, and the differing features will be described.

Referring to FIG. 9, a method of manufacturing the light-emitting element according to an embodiment may include preparing a preliminary light-emitting element (S100) and forming a light-emitting element (S200). The preparing of the preliminary light-emitting element (S100) may include: forming a first electrode EL1 (see FIGS. 12A and 12B); forming an emission layer EML (see FIGS. 12A and 12B) containing a quantum dot QD-C(see FIGS. 12A and 12B); forming a second electrode EL2 (see FIGS. 12A and 12B); forming an electron transport region P-ETR (see FIGS. 12A and 12B); and forming a hole transport region P-HTR (see FIGS. 12A and 12B).

In an embodiment, at least one of the forming of the electron transport region P-ETR (see FIGS. 12A and 12B) and the forming of the hole transport region P-HTR (see FIGS. 12A and 12B) may include providing a composition COP (see FIG. 10) that includes a preliminary metal nanoparticle P-NP (see FIG. 11). In an embodiment, one step among the forming of the electron transport region P-ETR (see FIGS. 12A and 12B) and the forming of the hole transport region P-HTR (see FIGS. 12A and 12B) may be performed between the forming of the first electrode EL1 (see FIGS. 12A and 12B) and the forming of the emission layer EML (see FIGS. 12A and 12B), and the remaining step among the forming of the electron transport region P-ETR (see FIGS. 12A and 12B) and the forming of the hole transport region P-HTR (see FIGS. 12A and 12B) may be performed between the forming of the emission layer EML (see FIGS. 12A and 12B) and the forming of the second electrode EL2 (see FIGS. 12A and 12B).

Hereinafter, the forming of the electron transport region P-ETR (see FIGS. 12A and 12B) will be described as being performed between the forming of the first electrode EL1 (see FIGS. 12A and 12B) and the forming of the emission layer EML (see FIGS. 12A and 12B), and the forming of the hole transport region P-HTR (see FIGS. 12A and 12B) will be described as being performed between the forming of the emission layer EML (see FIGS. 12A and 12B) and the forming of the second electrode EL2 (see FIGS. 12A and 12B). However, this is only shown for illustrative purposes, and embodiments are not limited thereto.

FIG. 10 is a schematic cross-sectional view of the forming of the electron transport region P-ETR (see FIGS. 12A and 12B) on the first electrode EL1. FIG. 11 is an enlarged schematic view of region AA′ in FIG. 10. FIG. 11 is a schematic cross-sectional view illustrating a composition COP. The composition COP including the preliminary metal nanoparticle P-NP (see FIG. 11) may be provided for forming the electron transport region P-ETR (see FIGS. 12A and 12B). For example, in an embodiment, the composition COP may be provided through an inkjet printing method or through a dispensing method. In FIG. 10, the composition COP is shown as being provided through a nozzle, but a device for providing the composition COP is not limited thereto.

Referring to FIG. 11, the composition COP may include a preliminary metal nanoparticle P-NP and a solvent CV. The solvent CV may be a material that enables the preliminary metal nanoparticle P-NP to be readily dispersed. The preliminary metal nanoparticle P-NP may include a core MC and a preliminary ligand P-LD. The preliminary ligand P-LD may shrink or may expand to thereby form a ligand LD (see FIG. 13). The preliminary ligand P-LD may include an acidic functional group, a basic functional group, or an ultraviolet-reactive functional group. The preliminary ligand P-LD including an acidic functional group, a basic functional group, or an ultraviolet-reactive functional group may shrink or may expand when the acidic functional group, the basic functional group, or the ultraviolet-reactive functional group is provided.

FIG. 12A is a schematic cross-sectional view illustrating an ultraviolet light that is provided to the preliminary light-emitting element P-ED, and FIG. 12B is a schematic cross-sectional view illustrating a basic material or an acidic material that is provided to the preliminary light-emitting element P-ED. The emission layer EML may be formed by providing a quantum dot composition including a quantum dot QD-C. The quantum dot composition may include a quantum dot QD-C and a solvent in which the quantum dot QD-C is dispersed. For example, the quantum dot QD-C may be dispersed in the solvent and may be provided through an inkjet printing method or through a dispensing method. The hole transport region P-HTR may be formed on the emission layer EML, and the second electrode EL2 may be formed on the hole transport region P-HTR.

The hole transport region P-HTR may be formed by providing the composition COP (see FIG. 11) including the preliminary metal nanoparticles P-NP (see FIG. 11). The core MC (see FIG. 11) of the preliminary metal nanoparticle P-NP (see FIG. 11), which is provided for forming the hole transport region P-HTR, may be different from the core MC (see FIG. 11) of the preliminary metal nanoparticle P-NP (see FIG. 11) that is provided for forming the electron transport region P-ETR. For example, the core MC (see FIG. 11) of the preliminary metal nanoparticle P-NP (see FIG. 11), which is provided for forming the hole transport region P-HTR, may include MoO₃, and the core MC (see FIG. 11) of the preliminary metal nanoparticle P-NP (see FIG. 11) that is provided for forming the electron transport region P-ETR, may include ZnO or ZMO. However, this is only explained as an example, and the material of the core MC is not limited thereto.

The ultraviolet light RA and the acidic material (or the basic material) GA may be provided after forming of the second electrode EL2. The acidic material (or the basic material) GA may be provided in a form of a gas. The acidic material (or the basic material) GA in the form of a gas may be provided with a gas providing device EV to the preliminary light-emitting element P-ED. For example, the acidic material GA may include at least one of isobutyric acid and citric acid. As another example, the basic material may include ammonia. However, this is only explained as an example, and the acidic material (or basic material) GA is not limited thereto.

The acidic material, the basic material, or the ultraviolet light may be provided only to a target light-emitting element (for example, at least one of the first to third light-emitting elements ED-1, ED-2, and ED-3). In an embodiment, when at least one quantum dot light-emitting element and at least one organic light-emitting element are provided (for example, when manufacturing the first to third light-emitting elements ED-1, ED-2, and ED-3) (see FIG. 4A to FIG. 4D), the acidic material, the basic material, or the ultraviolet light may be provided only to the at least one quantum dot light-emitting element. When the acidic material, the basic material, or the ultraviolet light are provided to an organic light-emitting element, the organic light-emitting element may be damaged. Accordingly, in an embodiment, the acidic material, the basic material, or the ultraviolet light should be provided only to a quantum dot light-emitting element. For example, the acidic material, the basic material, or the ultraviolet light may be provided only to the target light-emitting element. FIG. 10 to FIG. 13 are each a schematic view showing a method of manufacturing a quantum dot light-emitting element. For example, a hole transport region and an electron transport region of an organic light-emitting element including an organic emission material may each be formed through a deposition process.

FIG. 13 is an enlarged schematic view illustrating the electron transport region ETR after providing an acidic material (or a basic material) GA (see FIG. 12B). In FIG. 13, an electron transport region ETR is shown as an example, but a same or substantially similar description may be applied to a hole transport region HTR (see FIG. 5A to FIG. 5D).

An ultraviolet light RA (see FIG. 12A) or an acidic material (or a basic material) GA (see FIG. 12B) is provided to the preliminary ligand P-LD (see FIG. 11) to form the metal nanoparticle NP including the ligand LD. The preliminary ligand P-LD including the ultraviolet-reactive functional group may shrink or may expand by reacting to the ultraviolet light RA (see FIG. 12A). The preliminary ligand P-LD including the acidic functional group or the basic functional group may shrink or may expand by reacting with the acidic material GA or the basic material GA (see FIG. 12B).

In FIG. 11 and FIG. 13, the preliminary ligand P-LD (see FIG. 11) is shown to form the ligand LD by shrinking, but embodiments are not limited thereto. In an embodiment, the preliminary ligand P-LD (see FIG. 11) may expand to thereby form the ligand LD.

The electron transport region ETR may include abase part CR and metal nanoparticles NP dispersed in the base part CR. In an embodiment, the preliminary ligand P-LD (see FIG. 11) may shrink to form the ligand LD. Therefore, a gap between adjacent metal nanoparticles NP becomes narrow, and the metal nanoparticles NP become closer to each other. Accordingly, a density of the layer decreases, and a traveling path of light between metal nanoparticles NP increases in distance, which may lead to an improvement in efficiency of the light-emitting element ED.

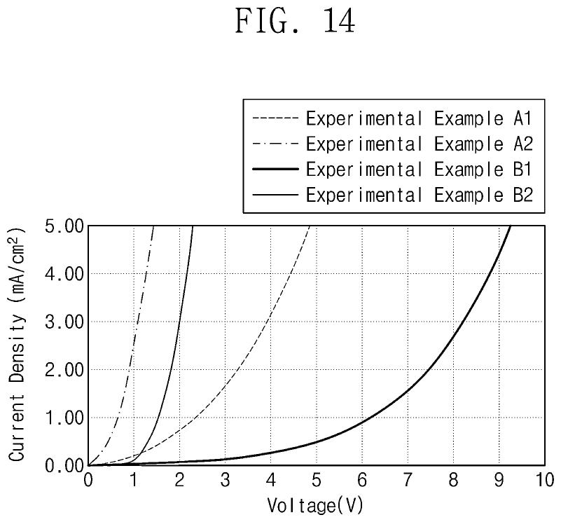

FIG. 14 is a graph showing a measured current density in electron only device (EOD) elements including the metal nanoparticles, across a range of driving voltages. For the elements according to Experimental Example A1, Experimental Example A2, Experimental Example B1, and Experimental Example B2, in the metal nanoparticle, the ligand includes an ultraviolet-reactive functional group, and the metal nanoparticle is included as an electron transport material. MgAg was used as an electrode material of the EOD element.

The elements according to Experimental Example A1, Experimental Example A2, Experimental Example B1, and Experimental Example B2 each include a metal nanoparticle formed of a core containing ZnO and ZMO, and the elements according to Experimental Example B1 and Experimental Example B2 each include an emission layer including a quantum dot. The elements according to Experimental Example A1 and Experimental Example A2 do not include an emission layer.

In Experimental Example A1 and Experimental Example A2, the light-emitting element according to Experimental Example A1 is an element before ultraviolet irradiation is provided, and the light-emitting element according to Experimental Example A2 is an element after ultraviolet irradiation is provided. In Experimental Example B1 and Experimental Example B2, the light-emitting element according to Experimental Example B1 is an element before ultraviolet irradiation is provided, and the light-emitting element according to Experimental Example B2 is an element after ultraviolet irradiation is provided. Ultraviolet light was irradiated at 1.5 J/cm² for 1 minute with a composite wavelength in a range of about 300 nm to about 600 nm.

Referring to FIG. 14, it can be seen that the light-emitting element according to Experimental Example A2 exhibits decreased driving voltage at the same current density compared to the light-emitting element according to Experimental Example A1. It can be seen that the light-emitting element according to Experimental Example B2 exhibits decreased driving voltage at the same current density, and exhibits decreased current density at the same driving voltage compared to the light-emitting element according to Experimental Example B1.

While ultraviolet irradiation is provided, MgAg that forms the electrode rapidly reacts with oxygen of the metal nanoparticle, and thus an interface between the electron transport region formed of the metal nanoparticle and the electrode is modified and an energy barrier is lowered, thereby increasing injection and/or transport of electrons. An energy level of a lowest unoccupied molecular orbital (LUMO) of the metal nanoparticle decreases, which enables electrons to be readily injected and/or transported. Therefore, in an embodiment, it can be seen that the metal nanoparticle NP (see FIG. 8) formed of the ligand LD (see FIG. 8) containing the ultraviolet-reactive functional group contributes to a decrease in driving voltage and an improvement in efficiency of the light-emitting elements ED and ED-a to ED-g (see FIG. 5A to FIG. 6D).

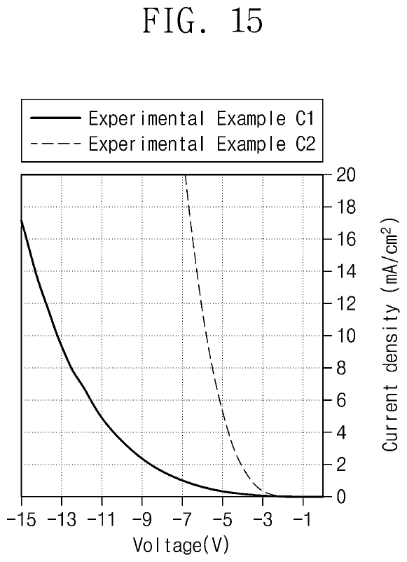

The light-emitting elements including the metal nanoparticle according to an embodiment were evaluated, and the results are shown in Table 1 and FIG. 15 below. The light-emitting elements according to Experimental Example C1 and Experimental Example C2 each include the metal nanoparticle according to an embodiment, formed of an ultraviolet-reactive functional group. The light-emitting element according to Experimental Example C1 is the same as the light-emitting element according to Experimental Example C2, except for the presence or absence of ultraviolet irradiation. The light-emitting element according to Experimental Example C1 is an element before ultraviolet irradiation is provided, and the light-emitting element according to Experimental Example C2 is an element after ultraviolet irradiation is provided. Ultraviolet light was irradiated at 120 W for 10 minutes with a composite wavelength in a range of about 300 nm to about 600 nm.

In Table 1, CIE_x and CIE_y represent CIE color coordinates, and λₘₐₓ represents a maximum emission wavelength. Driving voltage represents a value measured with respect to a current of 5 mA. The light-emitting element has a structure including an electron transport region below an emission layer, and a hole transport region on the emission layer. In FIG. 15, voltage is measured as a negative value, but the driving voltage value is an absolute value thereof. In Table 1, driving voltage is expressed as a positive value for convenience.

TABLE 1

| | Driving | Luminous | | | | Full width |
|---|---|---|---|---|---|---|
| | voltage | efficiency | | | γₘₐₓ | at half |
| | (V, @5 mA) | (Cd/A) | CIE_x | CIE_y | (nm) | maximum (nm) |
| Experimental | 11.06 | 1.60 | 0.701 | 0.299 | 639 | 37 |
| Example C1 | | | | | | |
| Experimental | 4.93 | 2.9 | 0.699 | 0.300 | 639 | 38 |
| Example C2 | | | | | | |

Referring to Table 1 and FIG. 15, the light-emitting element according to Experimental Example C2 has significantly lower driving voltage compared to the light-emitting element according to Experimental Example C1. Referring to Table 1, it can be seen that the light-emitting element according to Experimental Example C2 has improved luminous efficiency by 80% or more compared to the light-emitting element according to Experimental Example CL. It can be seen that the light-emitting element according to Experimental Example C1 and the light-emitting element according to Experimental Example C2 each have similar values of a maximum emission wavelength, a full width at half maximum, and CIE color coordinates. Accordingly, in an embodiment, it can be seen that the metal nanoparticle NP (see FIG. 8) formed of the ligand LD (see FIG. 8) including the ultraviolet-reactive functional group contributes to a decrease in driving voltage and an improvement in efficiency of the light-emitting elements ED and ED-a to ED-g (see FIG. 5A to FIG. 6D).

The light-emitting elements including the metal nanoparticle were evaluated and the evaluation results were listed in Table 2 below. The light-emitting elements according to Experimental Example D1 and Experimental Example D2 include metal nanoparticles formed of a basic functional group. The light-emitting element according to Experimental Example D1 is an element after an acidic material is provided, and the light-emitting element according to Experimental Example D2 is an element before an acidic material is provided. Isobutyric acid is provided as the acidic material. In Table 2, driving voltage V1 was measured with respect to a current density of 5 mA/cm², and driving voltage V2 was measured with respect to a luminance of 146 nits. Luminous efficiency, luminous efficiency L1, external quantum efficiency (EQE), CIE_x, and CIE_y were each measured with respect to a luminance of 146 nits. Luminous efficiency L1 is a value of luminous efficiency divided by CIE_y. CIE_x and CIE_y each represent CIE color coordinates.

TABLE 2

| | Driving | Driving | Luminous | Luminous | | | |
|---|---|---|---|---|---|---|---|
| | voltage V1 | voltage V2 | efficiency | efficiency | EQE | | |
| | (V, 5 mA/cm²) | (146 nit) | (cd/A) | L1 (cd/A/y) | (%) | CIE_x | CIE_y |
| Experimental | 6.2 | 5.7 | 6.5 | 101.5 | 12.8 | 0.130 | 0.064 |
| Example D1 | | | | | | | |
| Experimental | 6.7 | 6.4 | 3.6 | 53.1 | 6.9 | 0.129 | 0.069 |
| Example D2 | | | | | | | |

Referring to Table 2, it can be seen that the light-emitting elements according to Experimental Examples D1 and D2 exhibit similar color coordinates. It can be seen that the light-emitting element according to Experimental Example D1 has decreased driving voltage, and improved luminous efficiency by 90% or more, compared to the light-emitting element according to Experimental Example D2. It can be seen that, compared to the light-emitting element according to Experimental Example D2, the light-emitting element according to Experimental Example D1 has improved EQE. The light-emitting element according to Experimental Example Di contains a metal nanoparticle formed of a basic functional group according to an embodiment, after an acidic material is provided. Since the acidic material is provided, the ligand shrinks or expands, which leads to an adjustment of oxygen vacancy of the metal nanoparticle and improvements in electron injection and/or transport characteristics. Accordingly, in an embodiment, it can be seen that the light-emitting element including the metal nanoparticle formed of the ligand containing the basic functional group exhibits decreased driving voltage and excellent efficiency.

A method of manufacturing the light-emitting element according to an embodiment may include: providing a composition including a preliminary metal nanoparticle in the forming of at least one of the electron transport region and the hole transport region; and forming the light-emitting element by providing an acidic material, a basic material, or ultraviolet light. The metal nanoparticles may include an acidic functional group, a basic functional group, or an ultraviolet-reactive functional group, and may include a ligand bonded to a core. The ligand including an acidic functional group, a basic functional group, or an ultraviolet-reactive functional group may shrink or may expand by reacting with a basic material, an acidic material, or ultraviolet light, respectively.

The display device according to an embodiment may include the first to third light-emitting elements, each emitting light in a different wavelength region. At least one of the first to third light-emitting elements may include a quantum dot. In the light-emitting element including a quantum dot, according to an embodiment, at least one of the electron transport region and the hole transport region may include a metal nanoparticle. The metal nanoparticle that includes an acidic functional group, a basic functional group, or an ultraviolet-reactive functional group, and that includes a ligand bonded to a core may have improved charge injection and/or transport characteristics. Accordingly, the light-emitting element including the metal nanoparticle including the ligand may have decreased driving voltage and exhibit excellent efficiency.

The light-emitting element according to an embodiment and the display device including the light-emitting element includes the ligand that includes an acidic functional group, a basic functional group, or an ultraviolet-reactive functional group, which may contribute to excellent efficiency.

The method of manufacturing the light-emitting element according to an embodiment may include forming the light-emitting element by providing an acidic material, a basic material, or ultraviolet light, and thus the light-emitting element having excellent light efficiency may be manufactured.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting element comprising:
a first electrode;
a second electrode disposed on the first electrode;
an emission layer disposed between the first electrode and the second electrode, the emission layer including a quantum dot;
a hole transport region disposed between the first electrode and the second electrode; and
an electron transport region disposed between the first electrode and the second electrode, wherein
the emission layer is disposed between the hole transport region and the electron transport region,
at least one of the hole transport region and the electron transport region includes a metal nanoparticle,
the metal nanoparticle includes:
a core including a metal oxide; and
a ligand bonded to the core, the ligand including an acidic functional group, a basic functional group, or an ultraviolet-reactive functional group, and
the ultraviolet-reactive functional group shrinks or expands when ultraviolet light is provided.

2. The light-emitting element of claim 1, wherein the acidic functional group includes at least one of a carboxylic acid group, a phosphoric acid group, a sulfonic acid group, an amino acid group, and a boronic acid group.

3. The light-emitting element of claim 1, wherein the ligand including the acidic functional group is derived from at least one of acrylic acid (AAc), methacrylic acid (MAAc), ethylacrylic acid (EAAc), propylacrylic acid (PAAc), 4-vinylbenzoic acid (VBA), itaconic acid (IA), ethylene glycol acrylate phosphate (EGAP), vinylphosphonic acid (VPA), ethylene glycol methacrylate phosphate (EGMP), 4-vinyl-benzyl phosphonic acid (VBPA), vinylsulfonic acid (VSA), 4-styrenesulfonic acid (SSA), 2-acrylamido-2-methylpropane sulfonic acid (AMPS), 3-sulfopropyl methacrylate potassium salt (KSPMA), aspartic acid (ASA), L-glutamic acid (LGA), histidine (HIS), vinylphenyl boronic acid (VPBA), and (3-acrylamidophenyl boronic acid (AAPBA).

4. The light-emitting element of claim 1, wherein the basic functional group includes at least one of an amine group, a morpholino group, a pyrrolidine group, a piperazine group, a pyridine group, and an imidazole group.

5. The light-emitting element of claim 1, wherein the ligand including the basic functional group is derived from at least one of (2-dimethylamino)ethyl methacrylate (DMA), (2-diethylamino)ethyl methacrylate (DEA), (2-dipropylamino)ethyl methacrylate (DPAEMA), (2-diisopropylamino)ethyl methacrylate (DPA), (N-(3-(dimethylamino)-propyl)methacrylamide) (DMAPMAm), (2-dimethylamino)ethyl acrylate (DMAEA), 2-(tert-butylamino)ethyl methacrylate (tBAEMA), N,N-dimethylvinylbenzylamine, N,N-diethylvinylbenzylamine, N,N-dipropylvinylbenzylamine, (2-diethylamino)ethyl acrylamide (DEAm), (2-N-morpholino)ethyl methacrylate (MEMA), acryloylmorpholine (AM), (2-N-morpholino)ethyl methacrylamide (MEMAm), N-ethylpyrrolidine methacrylate (EPyM), N-acryloyl-N′-methyl piperazine, N-acryloyl-N′-ethyl piperazine, N-acryloyl-N′-propyl piperazine, 4-vinylpyridine (4VP), 2-vinylpyridine (2VP), N-vinylimidazole (VI), 6-(1H-imidazol-1-yl)hexyl-methacrylate (imHeMA), poly(propylenimine) dendrimer (PPI), poly(ethylenimine) dendrimer (PEI), and poly(amidoamine) dendrimer (PAMAM).

6. The light-emitting element of claim 1, wherein the ultraviolet-reactive functional group includes at least one of a spiropyran group and a merocyanine group.

7. The light-emitting element of claim 1, wherein the ligand including the ultraviolet-reactive functional group is derived from at least one compound selected from Compound Group 1: 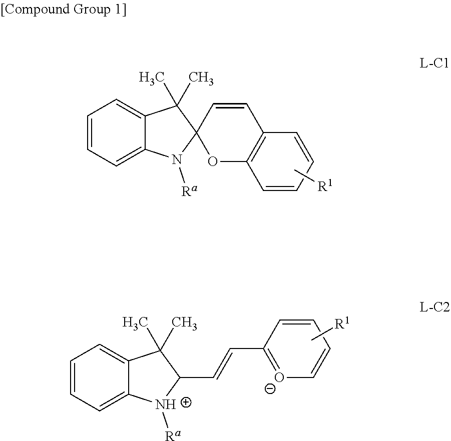
wherein in Compound Group 1,
R^{a} is a substituted or unsubstituted alkyl group having 1 to 20 carbon atoms, and
R¹ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

8. The light-emitting element of claim 1, wherein:
the metal oxide includes at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or
the metal oxide is represented by Formula M-1:
Zn_{q}Me_{(1-q)}O [Formula M-1]
wherein in Formula M-1,
q is a real number from 0 to 0.5, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

9. The light-emitting element of claim 1, wherein
the quantum dot includes a core part including an inorganic compound, and a ligand part that is bonded to the core part, and
the ligand part includes the acidic functional group or the basic functional group.

10. The light-emitting element of claim 1, wherein
the electron transport region includes the metal nanoparticle, and
the ligand includes the acidic functional group or the ultraviolet-reactive functional group.

11. The light-emitting element of claim 1, wherein
the hole transport region includes the metal nanoparticle, and
the ligand includes the basic functional group or the ultraviolet-reactive functional group.

12. The light-emitting element of claim 1, wherein
the hole transport region is disposed between the first electrode and the emission layer, and
the electron transport region is disposed between the emission layer and the second electrode.

13. The light-emitting element of claim 1, wherein
the hole transport region is disposed between the emission layer and the second electrode, and
the electron transport region is disposed between the first electrode and the emission layer.

14. A display device comprising:
a display element layer disposed on a base layer, wherein
the display element layer includes a first light emitting element, a second light emitting element, and a third light emitting element, each emitting light in a different wavelength region,
the first, second, and third light-emitting elements each comprises:
a first electrode;
a second electrode disposed on the first electrode;
an emission layer disposed between the first electrode and the second electrode;
a hole transport region disposed between the first electrode and the second electrode; and
an electron transport region disposed between the first electrode and the second electrode,
the emission layer is disposed between the hole transport region and the electron transport region,
at least one of the first to third light-emitting elements each includes a quantum dot in the emission layer,
the remainder of the first to third light-emitting elements each includes an organic emission material in the emission layer,
the light-emitting element including the quantum dot includes a metal nanoparticle in at least one of the hole transport region and the electron transport region,
the metal nanoparticle comprises:
a core including a metal oxide; and
a ligand bonded to the core, the ligand including an acidic functional group, a basic functional group, or an ultraviolet-reactive functional group, and
the ultraviolet-reactive functional group shrinks or expands when ultraviolet light is provided.

15. The display device of claim 14, wherein
the first light-emitting element emits blue light,
the second light-emitting element emits green light, and
the third light-emitting element emits red light.

16. The display device of claim 14, wherein
the first light-emitting element includes a first quantum dot emitting first light,
the second light-emitting element includes a second quantum dot emitting second light, which has a wavelength region that is different from the first light, and
the third light-emitting element includes an organic emission material emitting third light, which has a wavelength region that is different from the first light and the second light.

17. The display device of claim 14, wherein
the first light-emitting element includes a quantum dot emitting first light,
the second light-emitting element includes a first organic emission material emitting second light, which has a wavelength region that is different from the first light, and
the third light-emitting element includes a second organic emission material emitting third light, which has a wavelength region that is different from the first light and the second light.

18. The display device of claim 14, wherein
the first light-emitting element includes a first quantum dot emitting first light,
the second light-emitting element includes a second quantum dot emitting second light, which has a wavelength region that is different from the first light, and
the third light-emitting element includes a third quantum dot emitting third light, which has a wavelength region that is different from the first light and the second light.

19. The display device of claim 14, wherein the acidic functional group includes at least one of a carboxylic acid group, a phosphoric acid group, a sulfonic acid group, an amino acid group, and a boronic acid group.

20. The display device of claim 14, wherein the basic functional group includes at least one of an amine group, a morpholino group, a pyrrolidine group, a piperazine group, a pyridine group, and an imidazole group.

21. The display device of claim 14, wherein the ligand including the ultraviolet-reactive functional group is derived from at least one compound selected from Compound Group 1: 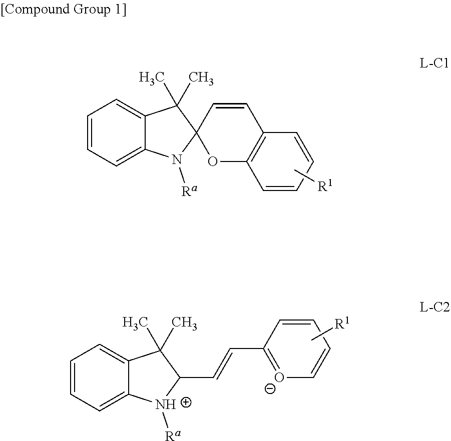
wherein in Compound Group 1,
R^{a} is a substituted or unsubstituted alkyl group having 1 to 20 carbon atoms, and
R¹ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

22. The display device of claim 14, wherein:
the metal oxide includes at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or
the metal oxide is represented by Formula M-1:
Zn_{q}Me_{(1-q)}O [Formula M-1]
wherein in Formula M-1,
q is a real number from 0 to 0.5, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

23. A method of manufacturing a light-emitting element, the method comprising:
preparing a preliminary light-emitting element; and
forming a light-emitting element by providing, to the preliminary light-emitting element, an acidic material, a basic material, or ultraviolet light, wherein
the preparing of the preliminary light-emitting element comprises:
forming a first electrode;
forming an emission layer by providing a quantum dot on the first electrode;
forming a second electrode on the emission layer;
forming a hole transport region; and
forming an electron transport region,
one step among the forming of the hole transport region and the forming of the electron transport region is performed between the forming of the first electrode and the forming of the emission layer, and
the remaining step among the forming of the hole transport region and the forming of the electron transport region is performed between the forming of the emission layer and the forming of the second electrode,
at least one of the forming of the hole transport region and the forming of the electron transport region includes providing a composition that includes a preliminary metal nanoparticle,
the preliminary metal nanoparticle comprises:
a core including a metal oxide; and
a preliminary ligand bonded to the core, the ligand including an acidic functional group, a basic functional group, or an ultraviolet-reactive functional group
the ultraviolet-reactive functional group shrinks or expands when the ultraviolet light is provided.

24. The method of claim 23, wherein the preliminary ligand shrinks or expands to form a ligand when the acidic material, the basic material, or the ultraviolet light is provided.

25. The method of claim 23, wherein the acidic material includes at least one of isobutyric acid and citric acid.

26. The method of claim 23, wherein the basic material includes ammonia.

27. The method of claim 23, wherein the composition is provided through an inkjet printing method or through a dispensing method.

28. The method of claim 23, wherein the acidic functional group includes at least one of a carboxylic acid group, a phosphoric acid group, a sulfonic acid group, an amino acid group, and a boronic acid group.

29. The method of claim 23, wherein the basic functional group includes at least one of an amine group, a morpholino group, a pyrrolidine group, a piperazine group, a pyridine group, and an imidazole group.

30. The method of claim 23, wherein the ligand including the ultraviolet-reactive functional group is derived from at least one compound selected from Compound Group 1: 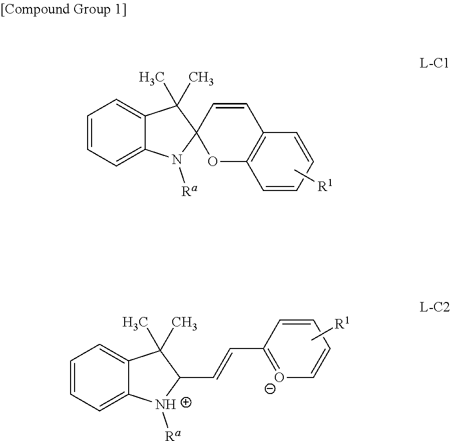
wherein in Compound Group 1,
R^{a} is a substituted or unsubstituted alkyl group having 1 to 20 carbon atoms, and
R¹ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

31. The method of claim 23, wherein:
the metal oxide includes at least one of SnO, SnO₂, CuGaO₂, Ga₂O₃, Cu₂O, SrCu₂O₂, SrTiO₃, CuAlO₂, Ta₂O₅, NiO, BaSnO₃, MoO₃, and TiO₂; or
the metal oxide is represented by Formula M-1:
Zn_{q}Me_{(1-q)}O [Formula M-1]
wherein in Formula M-1,
q is a real number from 0 to 0.5, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.
